(19) United States
(12) Patent Application Publication
(10) Pub. No.: US 2025/0341594 A1
(43) Pub. Date: Nov. 6, 2025

(54) STRUCTURES, METHODS, AND TECHNIQUES FOR DECREASING A LATERAL DIMENSION OF TUNNELING MAGNETORESISTANCE PILLARS

(71) Applicant: Allegro MicroSystems, LLC, Manchester, NH (US)

(72) Inventors: Paolo Campiglio, Arcueil (FR); Yen Ting Liu, Hsinchu City (TW); Maxim Klebanov, Palm Coast, FL (US); Pierrick Charlier, Palaiseau (FR)

(73) Assignee: Allegro MicroSystems, LLC, Manchester, NH (US)

(21) Appl. No.: 18/652,971

(22) Filed: May 2, 2024

(51) Int. Cl. G01R 33/09

(52) U.S. Cl. CPC G01R 33/098

(57) ABSTRACT

Disclosed are example structures that have tunneling magnetoresistance (TMR) pillars with a decreased lateral dimension. Also described are methods and techniques for forming these structures. Also described herein are structures, and methods and techniques for forming structures, where a conductive hard mask may be provided on top of TMR pillars for direct contact with a top metal layer. Using the methods and techniques described herein, TMR pillars with a decreased lateral dimension may be utilized in structures.

### BACKGROUND

As is known, sensor devices are used to measure and monitor properties of systems in a wide variety of applications. For example, sensor devices have become common in products that rely on electronics in their operation, such as automotive and motor control systems.

Some sensor devices monitor properties by detecting a magnetic field associated with proximity or movement of a target. These sensor devices may include one or more magnetic field sensing elements to detect the magnetic field. Known examples of magnetic field sensing elements include Hall effect elements, magnetoresistance elements, and magnetotransistor elements. As is known, there are different types of Hall effect elements, including, for example, planar Hall effect elements, vertical Hall elements, and circular vertical Hall (CVH) elements. There are also different types of magnetoresistance elements, including, for example, semiconductor magnetoresistance elements such as Indium Antimonide (InSb) elements, spin valve elements, giant magnetoresistance (GMR) elements, anisotropic magnetoresistance (AMR) elements, magnetic tunnel junction (MTJ) elements, and tunneling magnetoresistance (TMR) elements. A magnetic field sensing element may include a single element, or alternatively, may include two or more magnetic field sensing elements arranged in various configurations, such as half bridge or full (Wheatstone) bridge configurations. Depending on the device type and other application requirements, a magnetic field sensing element may be a device made of a type IV semiconductor such as Silicon (Si) or Germanium (Ge), or a type III-V semiconductor such as Gallium-Arsenide (GaAs) or an Indium compound such as Indium-Antimonide (InSb).

### SUMMARY

Disclosed are example structures that have tunneling magnetoresistance (TMR) elements with a decreased lateral dimension. Also described are methods and techniques for forming these structures. In particular, disclosed are structures, and methods and techniques for forming structures, where cushion pads accommodating more than one TMR element may be provided. Also described herein are structures, and methods and techniques for forming structures, where a conductive hard mask may be provided on top of a TMR element for direct contact with a top metal layer. Using the methods and techniques described herein, TMR elements with a decreased lateral dimension may be utilized in structures.

In accordance with some embodiments, a structure is provided. The structure comprises a first conductive layer, a second conductive layer, and a third conductive layer. The structure also comprises a first set of at least two tunneling magnetoresistance (TMR) elements in direct contact with the first conductive layer and with the second conductive layer, each of the at least two TMR elements of the first set comprising a free layer, a barrier layer, and a reference layer. The structure further comprises a second set of at least two TMR elements in direct contact with the third conductive layer and with the second conductive layer, each of the at least two TMR elements of the second set comprising a free layer, a barrier layer, and a reference layer.

In some embodiments, each of the at least two TMR elements of the first set has a first surface in direct contact with the first conductive layer and a second surface in direct contact with the second conductive layer. Each of the at least two TMR elements of the second set also has a first surface in direct contact with the third conductive layer and a second surface in direct contact with the second conductive layer.

In further embodiments, each of the first conductive layer and the third conductive layer comprises Titanium Nitride (TiN).

In still further embodiments, the second conductive layer comprises one of Copper (Cu) or Aluminum (Al).

In some embodiments, the first surface of each of the at least two TMR elements of the first set is in direct contact with a first side of the first conductive layer, and an area of the first side of the first conductive layer is greater than a combined area of the first surfaces of the at least two TMR elements of the first set.

In further embodiments, each of the at least two TMR elements of the first set is in direct contact with a first side of the first conductive layer, and a second side of the first conductive layer is in direct contact with a plurality of vias, each of the vias being filled with a conductive material for electrically connecting the first conductive layer to a metal substrate.

In still further embodiments, resistances of a TMR element of the first set and a TMR element of the second set are connected in series.

In some embodiments, resistances of each of the at least two TMR elements in the first set are connected in parallel.

In further embodiments, each of the at least two TMR elements in the first set is in direct contact with a first side of the first conductive layer, and a second side of the first conductive layer is in direct contact with a first via, the first via being filled with a conductive material for electrically connecting the first conductive layer to a first metal substrate. The substrate further comprises a fourth conductive layer indirectly coupled to the first conductive layer, wherein the fourth conductive layer is in direct contact with a second via, the second via being filled with a conductive material for electrically connecting the fourth conductive layer to a second metal substrate.

In still further embodiments, the structure further comprises a third metal substrate configured for connection to a current source such that, when current is applied to the third metal substrate, the third metal substrate heats and radiates a magnetic field that changes a biasing of the at least two TMR elements in the first set and in each of the at least two TMR elements in the second set.

In some embodiments, the structure further comprises a third set of at least two TMR elements in direct contact with the fourth conductive layer, each of the at least two TMR elements of the third set comprising a free layer, a barrier layer, and a reference layer.

In further embodiments, the structure further comprises a fifth conductive layer, wherein a TMR element of the third set has a first surface in direct contact with the third conductive layer and a second surface in direct contact with the fifth conductive layer, the fifth conductive layer being indirectly coupled to the first conductive layer.

In still further embodiments, a first side of the second conductive layer is in direct contact with each of the at least two TMR elements of the first set and is further in direct contact with at least one via, the at least one via being filled with a conductive material for electrically connecting the second conductive layer to a metal substrate.

Furthermore, in accordance with some embodiments, there is provided a method for forming a structure. The method comprises providing a first conductive layer and a second conductive layer on a substrate, and forming a tunnel magnetoresistance (TMR) structure on the first conductive layer and the second conductive layer, the TMR structure comprising at least a reference layer, a barrier layer, and a free layer. The method also comprises depositing a mask metal layer on top of the TMR structure, and forming a third conductive layer and a fourth conductive layer from the mask metal layer. The method further comprises forming a first TMR element and a second TMR element from the TMR structure. The method still further comprises depositing a top metal layer onto the third conductive layer and the fourth conductive layer, wherein the first TMR element is coupled to the top metal layer through the third conductive layer and the second TMR element is coupled to the top metal layer through the fourth conductive layer.

In some embodiments, the method further comprises providing a first via in the substrate, the first via being filled with a conductive material, and providing the first conductive layer in direct contact with the first via.

In further embodiments, the method further comprises depositing an etch stop material in direct contact with the TMR structure, and depositing the mask metal layer in direct contact with the etch stop material.

In still further embodiments, the method further comprises depositing a photoresist material in a pattern on top of the mask metal layer. The method still further comprises etching the mask metal layer based on the pattern of the photoresist material to form the third conductive layer and the fourth conductive layer, and removing the photoresist material.

In some embodiments, the method further comprises etching the TMR structure with an ion beam etching process to form the first TMR element and the second TMR element.

In further embodiments, the method further comprises depositing a passivation layer over the first conductive layer, second conductive layer, third conductive layer, fourth conductive layer, first TMR element, and second TMR element.

In still further embodiments, the method further comprises performing a chemical mechanical polishing process to etch back the passivation layer, such that a top of the third conductive layer and a top of the fourth conductive layer are exposed.

In some embodiments, the method further comprises depositing the top metal layer onto the top of the third conductive layer and the top of the fourth conductive layer.

In further embodiments, the method further comprises depositing one or more additional passivation layers over the top metal layer.

Additionally, in accordance with some embodiments, there is provided a structure. The structure comprises a first conductive layer, a second conductive layer, and a third conductive layer in direct contact with the second conductive layer. The structure also comprises at last two tunneling magnetoresistance (TMR) elements in direct contact with the first conductive layer and indirectly coupled to the third conductive layer, each of the at least two TMR elements comprising a free layer, a barrier layer, and a reference layer. In the structure, a first surface of one of the at least two TMR elements is coupled to a first surface of the second conductive layer via an etch stop material, and a surface area of the first surface of the one TMR element is the same as the surface area of the first surface of the second conductive layer.

In some embodiments, the first surface of the second conductive layer is no wider than 0.5 microns.

In further embodiments, the first conductive layer comprises Titanium Nitride (TiN).

In still further embodiments, the second conductive layer comprises one of Aluminum (Al), Titanium Nitride (TiN), or Copper Nitride (CuN).

In some embodiments, the third conductive layer comprises one of Copper (Cu) or Aluminum (Al).

In further embodiments, the etch stop material comprises Titanium Nitride (TiN).

Before explaining example embodiments consistent with the present disclosure in detail, it is to be understood that the disclosure is not limited in its application to the details of constructions and to the arrangements set forth in the following description or illustrated in the drawings. The disclosure is capable of being practiced and carried out in various ways. Also, it is to be understood that the phraseology and terminology employed herein, as well as in the abstract, are for the purpose of description and should not be regarded as limiting.

It is to be understood that both the foregoing general description and the following detailed description are explanatory only and are not restrictive of the claimed subject matter.

### BRIEF DESCRIPTION OF THE DRAWINGS

The accompanying drawings are incorporated in and constitute part of this specification. The drawings, together with the description, illustrate and serve to explain the principles of various example embodiments of the disclosure.

FIG. 1 shows a diagram of an example magnetic field sensor having tunneling magnetoresistance (TMR) element structures.

FIG. 2 shows a block diagram of an example TMR pillar.

FIG. 3A shows a cross-section of an example structure having one TMR pillar per cushion pad, and multiple vias per cushion pad.

FIG. 3B shows a top view of an example connection arrangement of a structure having one TMR pillar per cushion pad and multiple vias per cushion pad, where TMR pillars are connected in series.

FIG. 3C shows a top view of an example connection arrangement of a structure having one TMR pillar per cushion pad and multiple vias per cushion pad, where TMR pillars are connected in parallel.

FIG. 4A shows a cross section of an example structure having one TMR pillar per cushion pad and one via per cushion pad.

FIG. 4B shows a top view of an example connection arrangement of a structure having one TMR pillar per cushion pad and one via per cushion pad, where TMR pillars are connected in series.

FIG. 4C shows a top view of an example connection arrangement of a structure having one TMR pillar per cushion pad and one via per cushion pad, where TMR pillars are connected in parallel.

FIG. 5A shows a cross section of an example structure having multiple TMR pillars per cushion pad and multiple vias under the cushion pad, consistent with embodiments of the present disclosure.

FIG. 5B shows a top view of an example connection arrangement of a structure having multiple TMR pillars per cushion pad, consistent with embodiments of the present disclosure.

FIG. 5C shows another top view of another example connection arrangement of a structure having multiple TMR pillars per cushion pad, consistent with embodiments of the present disclosure.

FIG. 6A shows a cross section of an example structure having multiple TMR pillars per cushion pad and vias at ends of some cushion pads, consistent with embodiments of the present disclosure.

FIG. 6B shows a top view of an example connection arrangement of a structure having multiple TMR pillars per cushion pad and vias at ends of some cushion pads, consistent with embodiments of the present disclosure.

FIG. 7A shows a cross section of an example structure having multiple TMR pillars per cushion pad without vias under the cushion pads, consistent with embodiments of the present disclosure.

FIG. 7B shows a top view of an example connection arrangement of a structure having multiple TMR pillars per cushion pad without vias under the cushion pads, consistent with embodiments of the present disclosure.

FIG. 8 shows a diagram of a process for utilizing a conductive hard mask to connect a TMR pillar to a top metal, consistent with embodiments of the present disclosure.

FIG. 9 shows an example process for forming a structure having multiple TMR pillars per cushion pad, consistent with embodiments of the present disclosure.

FIG. 10 shows an example process for forming a structure having multiple TMR pillars per cushion pad without vias under the cushion pad, consistent with embodiments of the present disclosure.

FIG. 11 shows an example process for forming a structure utilizing a conductive hard mask to connect a TMR pillar to a top metal, consistent with embodiments of the present disclosure.

The drawings are not necessarily to scale, or inclusive of all elements of a structure, method, or technique, emphasis instead generally being placed upon illustrating the concepts, structures, methods, and techniques sought to be protected herein.

### DETAILED DESCRIPTION

Disclosed are example structures that have tunneling magnetoresistance (TMR) elements (e.g., TMR pillars) with a decreased lateral dimension (e.g., decreased width). Also described are methods and techniques for forming these structures. In particular, disclosed are structures, and methods and techniques for forming structures, where cushion pads accommodating more than one TMR pillar may be provided. Also described herein are structures, and methods and techniques for forming structures, where a conductive hard mask may be provided on top of TMR pillars for direct contact with a top metal layer. Using the methods and techniques described herein, TMR pillars with a decreased lateral dimension may be utilized in structures.

As is known, sensor devices are used to measure and monitor properties of systems in a wide variety of applications. For example, sensor devices have become common in products that rely on electronics in their operation, such as automotive and motor control systems.

Some sensor devices monitor properties by detecting a magnetic field associated with proximity or movement of a target. These sensor devices may include one or more magnetic field sensing elements to detect the magnetic field. Known examples of magnetic field sensing elements include Hall effect elements, magnetoresistance elements, and magnetotransistor elements. As is known, there are different types of Hall effect elements, including, for example, planar Hall effect elements, vertical Hall elements, and circular vertical Hall (CVH) elements. There are also different types of magnetoresistance elements, including, for example, semiconductor magnetoresistance elements such as Indium Antimonide (InSb) elements, spin valve elements, giant magnetoresistance (GMR) elements, anisotropic magnetoresistance (AMR) elements, magnetic tunnel junction (MTJ) elements, and tunneling magnetoresistance (TMR) elements. A magnetic field sensing element may include a single element, or alternatively, may include two or more magnetic field sensing elements arranged in various configurations, such as half bridge or full (Wheatstone) bridge configurations. Depending on the device type and other application requirements, a magnetic field sensing element may be a device made of a type IV semiconductor such as Silicon (Si) or Germanium (Ge), or a type III-V semiconductor such as Gallium-Arsenide (GaAs) or an Indium compound such as Indium-Antimonide (InSb).

An object monitored by a sensor device is often referred to as a target. Accordingly, an object (e.g., magnet) whose characteristics are sensed by a sensor device may be referred to as a “target” herein.

The terms “connect,” “connected,” “connection,” “wired,” “interface,” “interfaced,” or “coupled” herein should be interpreted to mean any way of electrically and/or mechanically connecting materials, components, parts, or systems. For example, an electrical and/or mechanical connection, interface, or coupling may be established using wires, cables, traces on a printed circuit board (PCB), or interconnects within a structure, such as in an integrated circuit (IC) or package. The word “coupled,” as used herein, may refer to a mechanical or electrical coupling. The term “directly coupled” should be interpreted to mean that the materials “directly coupled” are in direct contact with each other. The term “indirectly coupled” should be interpreted to mean that the materials are not in direct contact with each other, but may be indirectly coupled together through another material, such as electrically coupled through another conductive material.

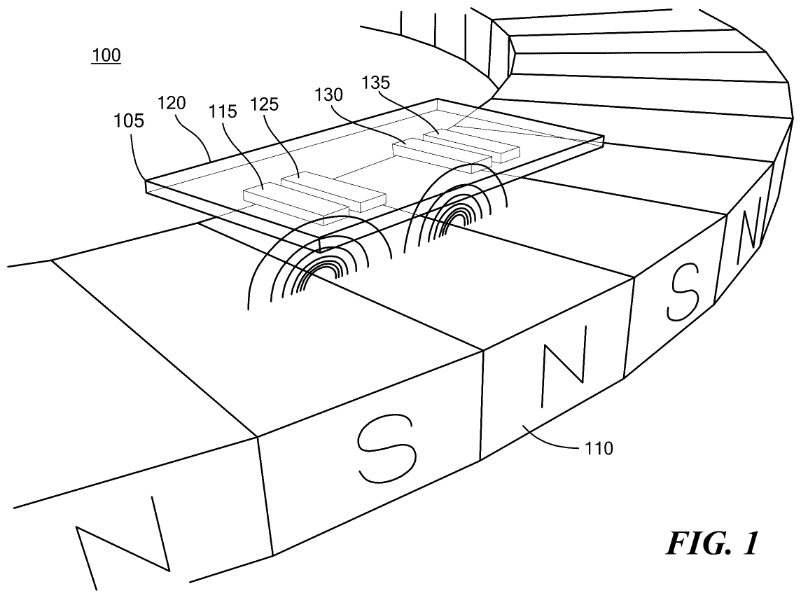

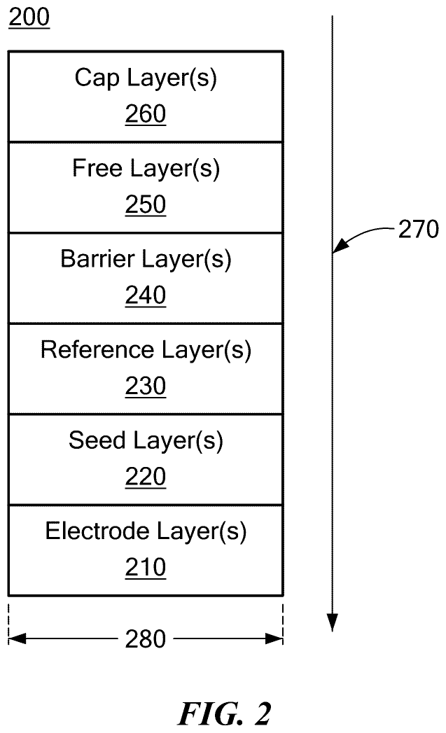

FIG. 1 shows a diagram 100 of an example magnetic field sensor device 120 having magnetic field sensing element structures (here, four structures 115, 125, 130, 135 comprising TMR elements). Each of the magnetic field sensing element structures may include one or more TMR pillars (see, e.g., FIG. 2). In some embodiments, magnetic field sensing element structures 115, 125, 130, 135 may be coupled in bridge arrangements. Magnetic field sensing element structures 115, 125, 130, 135 may be positioned on a substrate 105. Additional electronic components (not shown), for example, amplifiers, analog-to-digital (ADC) converters, and/or controllers may also be disposed on substrate 105 and coupled to one or more of TMR element structures 115, 125, 130, 135.

As shown in FIG. 1, magnetic field sensor 120 may be disposed proximate to a moving target, such as a ring magnet 110 having alternating north and south magnetic poles. Ring magnet 110 may be subject to motion (e.g., rotation) and magnetic field sensing element structures 115, 125, 130, 135 of magnetic field sensor 120 may be oriented such that axes of magnetic field sensing element structures 115, 125, 130, 135 are aligned and responsive with a magnetic field generated by ring magnet 110.

Magnetic field sensing element structures 115, 125, 130, 135 may be driven by one or more voltage sources and configured to generate one or more signals representative of the magnetic field generated by ring magnet 110. For example, TMR elements within magnetic field sensing element structures 115, 125, 130, 135 may exhibit a resistance that changes in response to a magnetic field, causing different amounts of current to flow through the TMR elements depending on the applied magnetic field. Signals representative of these currents (and therefore representative of the magnetic field) may be generated, and sensor device 120 may use the signals to determine characteristics of ring magnet 110, such as direction of rotation, proximity, position, angle of rotation, and/or speed of rotation. In some embodiments, ring magnet 110 may be coupled to a rotation object, such as a cam shaft in an engine, and a determined characteristic of ring magnet 110 may be indicative of a related characteristic of the rotation object.

FIG. 1 is just one example application of a sensor device with magnetic field sensing element structures being used to detect a magnetic field of one type of target (e.g., ring magnet 110). The disclosure is not limited to this example. For example, a person of ordinary skill in the art would recognize that any form of magnet may be used as a target, including, for example, disc magnets, bar magnets, horseshoe magnets, cylinder magnets, or any other form of magnet. A person of ordinary skill in the art would also recognize that a target may be a metal capable of being magnetized (e.g., a ferromagnetic object) and a separate magnet may be placed in proximity to the target, such that movement of the target causes magnetic field variations to be detected by the sensor device.

A person of ordinary skill in the art would also recognize that a magnetic target may be a permanent magnet that stays magnetized once magnetized, a temporary magnet that behaves like a magnet only when near a magnetic field, an electromagnet that behaves like a magnet only when electricity is applied, or any other type of magnet. A person of ordinary skill in the art would recognize that a magnetic target may be made of any type of magnetic material, such as neodymium (e.g., neodymium-iron-boron (NdFeB)), samarium cobalt (e.g., SmCo), alnico (e.g., aluminum, nickel, cobalt), ceramic or ferrite (e.g., strontium carbonate, iron oxide), or any other type of magnetic material. A magnetic target may be diametrically magnetized and/or axially magnetized. A magnetic target may have any number of alternating north and south poles.

FIG. 2 shows a block diagram of an example TMR element structure, here a TMR pillar 200. A TMR pillar may have a lateral dimension 280 (i.e., width of TMR pillar). The lateral dimension may measure less than 1 micron, for example, though the disclosure is not so limited and a TMR pillar having any width may be constructed. TMR pillar 200 may include a stack of layers 210-260. For example, electrode layer(s) 210 may comprise one or more conductive material layers, such as one or more metal layers. Seed layer(s) 220 may be positioned on top of electrode layer(s) 210 and may comprise one or more copper nickel (CuN) layers, for example. Reference layer(s) 230 may be positioned on top of seed layer(s) 220 and may comprise, for example, one or more platinum manganese (PtMn) layers, iridium manganese (IrMn) layers, cobalt iron (CoFe) layers, and/or cobalt iron boron (CoFeB) layers. For example, in some embodiments, reference layer(s) 230 may include a first layer of PtMn or IrMn on top of seed layer(s) 220, a second layer of CoFe on top of the first layer, a third layer of Ru on top of the second layer, and a fourth layer of CoFeB on top of the third layer.

Barrier layer(s) 240 may be positioned on top of reference layer(s) 230 and may include one or more layers of magnesium oxide (MgO), for example. Free layer(s) 250 may be positioned on top of barrier layer(s) 240 and may include one or more layers of CoFeB, for example. Cap layer(s) 260 may be positioned on top of free layer(s) 250 and may include one or more layers of tantalum (Ta), for example.

In some embodiments, one or more layers of reference layer(s) 230 may be a pinned layer that is magnetically coupled to one or more other layers of reference layer(s) 230. For example, a layer of CoFe may be positioned on top of a layer of PtMn in reference layer(s) 230, and the layer of CoFe may be a pinned layer that is magnetically coupled to a layer of PtMn. The physical mechanism coupling the layer of CoFe and the layer of PtMn together is sometimes referred to as an exchange bias.

Free layer(s) 250 may include a layer of CoFeB. In some embodiments, free layer(s) 250 may include an additional layer of nickel iron (NiFe) and a thin layer of Ta between the CoFeB layer and the NiFe layer.

A TMR pillar 200 may be driven by a voltage, such that a current runs in a direction through the TMR pillar through the layers of the stack (e.g., direction 270 or opposite direction of 270), running between cap layer(s) 260 and electrode layer(s) 210 (i.e., through the layers 210-260 and perpendicular to a surface of electrode layer(s) 210).

Electrode layer(s) 210 may be connected to other components of an electronic circuit or structure. For example, electrode layer(s) 210 may be positioned on an electroconductive interface of some sort.

A person of ordinary skill in the art would understand that FIG. 2 and the above description with reference to FIG. 2 provides just one example construction of a TMR pillar for context. A person of ordinary skill in the art would recognize that there are many ways to construct TMR pillars. The disclosure herein should not be limited to the example shown and described with respect to FIG. 2, and should be considered to encompass other known ways of constructing TMR pillars.

The term “layer” as used herein, may refer to one or more materials in a structure. The term “layer” may refer to one or more materials stacked on top, beneath, or to the side of one or more other materials, and should not be interpreted as limiting the orientation or positioning of the one or more materials to any other materials in a structure.

The terms “insulation” or “insulator,” as used herein with reference to materials, refers to materials that are not electrically conductive and are rather electrical insulators. The terms “conductive” or “electroconductive” as used herein with reference to materials, refers to materials that are electrically conductive.

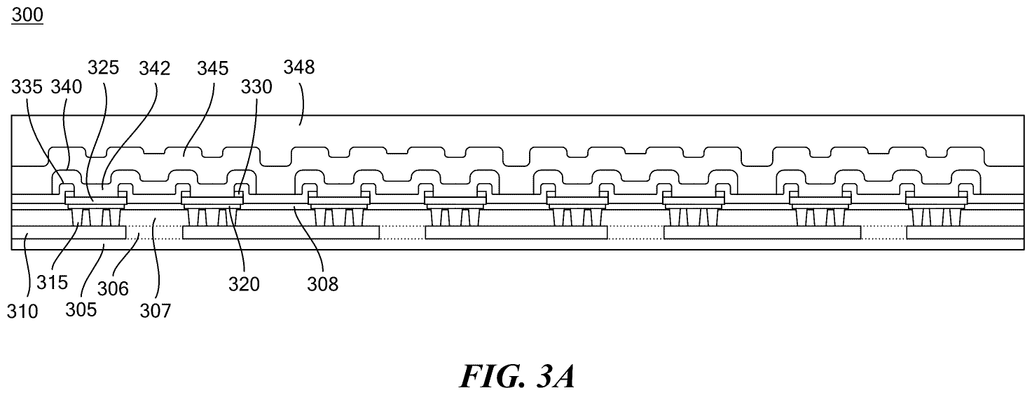

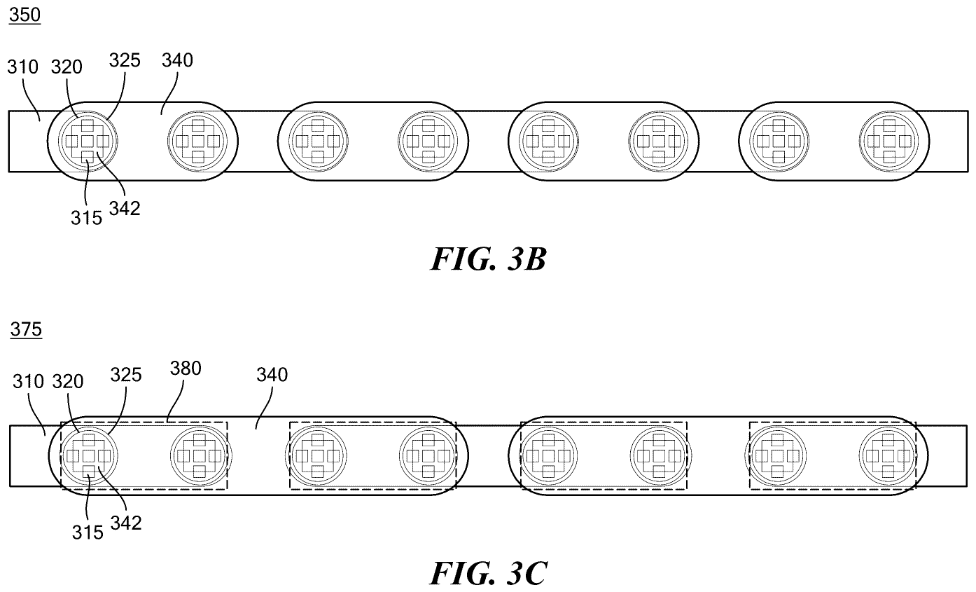

FIG. 3A shows a cross-section of an example magnetic field sensing structure 300 having one TMR element (e.g., TMR pillar 325) per cushion pad 320, and multiple bottom vias 315 per cushion pad. Structure 300 may, for example, be a magnetic field sensing element (e.g., magnetic field sensing element 115, 125, 130, 135). As shown, the structure may be constructed of several sheets of materials arranged in a stack. The first (e.g., bottom) one or more sheets 305 of materials in the stack may be constructed of an insulation material. Any suitable insulation material may be used, such as Silicon Dioxide (SiO₂) or Silicon Nitride (SiN). In some embodiments, sheet(s) 305 may comprise a Silicon wafer. In the example shown in FIG. 3A, one or more sheets 306 of an insulation material (e.g., SiO₂) with one or more layers of a metal substrate 310 may be stacked atop sheet(s) 305. Metal substrate layer(s) 310 may be patterned into sheet(s) 306, and may be formed of a conductive material. Any known technique for patterning conductive material into an insulator material may be used to pattern metal substrate layer(s) 310 into sheet(s) 306. Any conductive material may be used, such as aluminum (Al). In the cross-section of example structure 300 shown in FIG. 3A, five layers 310 of metal substrate patterned into sheet(s) 306 can be seen.

In the example shown in FIG. 3A, one or more sheets 307 of an insulation material (e.g., SiO₂) with one or more bottom vias 315 may be stacked atop sheet(s) 306. Bottom via(s) 315 may be patterned into sheet(s) 307. Any known technique for patterning vias into an insulator material may be used to pattern bottom via(s) 315 into sheet(s) 307. Bottom via(s) 315 may be filled with a conductive material. Any conductive material may be used, such as Tungsten (W). In the cross-section of example structure 300 shown in FIG. 3A, twenty-four bottom vias 315 patterned into sheet(s) 307 can be seen.

In the example shown in FIG. 3A, one or more sheets 308 of an insulation material (e.g., SiO₂) with one or more cushion pads 320 may be stacked atop sheet(s) 307. Cushion pad(s) 320 may be patterned into sheet(s) 308, and may be formed of one or more layers of conductive material. Any known technique for patterning a conductive material into an insulator material may be used to pattern cushion pad(s) 320 into sheet(s) 308. In some embodiments, cushion pad(s) 320 may be formed of one or more layers of conductive material with a flat and smooth surface. The flat and smooth surface may improve performance of a TMR pillar formed on top of the cushion pad. The flat and smooth surface may also improve performance of a conductive interconnection between a TMR pillar and a metal substrate. A cushion pad 320 may comprise any type of conductive material, for example, Titanium Nitride (TiN), CuN, or W. In the cross-section of example structure 300 shown in FIG. 3A, eight cushion pads 320 can be seen.

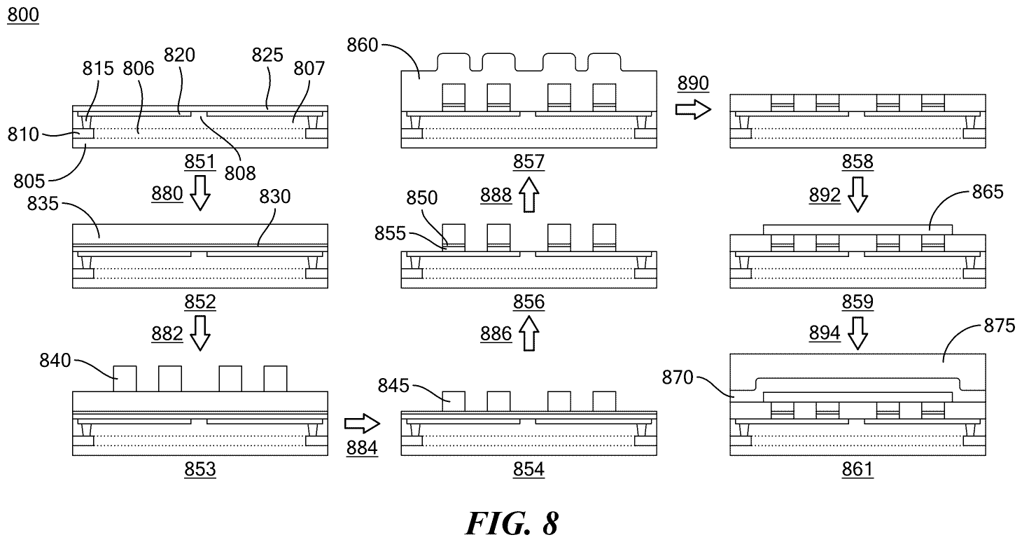

In the example shown in FIG. 3A, TMR pillars 325 may be constructed on top of cushion pads 320. In some embodiments, TMR pillars 325 may be constructed on top of cushion pads such that, for each of the TMR pillars, a first surface of the TMR pillar is in direct contact with a first surface of the cushion pad. FIG. 3A shows a construction with one TMR pillar 325 per cushion pad 320. A TMR pillar 325 may be constructed of multiple layers, such as TMR pillar 200 of FIG. 2. In the cross-section of example structure 300 shown in FIG. 3A, eight TMR pillars 325 can be seen, one for each cushion pad 320 that can be seen. In some embodiments, the TMR pillars may be constructed by first depositing the layers of the TMR pillars as sheets of materials in a TMR structure that extends across structure 300 (see, e.g., 825 of FIG. 8). One or more layers of materials may then be applied on top of the TMR structure and etched into a pattern on the TMR structure (see, e.g., 835, 840 of FIG. 8). For example, one or more layers of hard mask material may be applied on top of the TMR structure. The layer(s) of hard mask material may be etched to form a pattern of hard mask material, and that pattern may then be used to etch the TMR structure into separate TMR pillars (see, e.g., FIG. 8), such as shown in FIG. 3A. Deposition of mask layer(s) and etching processes may be performed as known in the art, such as through use of a soft mask, photoresist, or hard mask, the etching performed through, for example, photolithography or ion beam etching. FIG. 3A shows portions of layer(s) 330 of hard mask material that may remain on top of each of the TMR pillars in structure 300 as a result of the photolithography/etching process.

The term “hard mask,” as used herein, describes a type of barrier that is used during a photolithography or etching process, and can be distinguished from a photoresist mask (i.e., soft mask). For example, a hard mask may include material such as SiO₂, SiN, polysilicon, and/or oxide-nitride-oxide (ONO). A hard mask may also be conductive. Conductive hard masks may be made of a conductive material, such as a metal (e.g., Al, TiN, CuN). Any other suitable material may be used to form a hard mask, such as any materials that can a) withstand oxidation process (i.e., not get burnt in a furnace) and/or b) provide a barrier against oxidation of silicon layers underneath.

In constructing structure 300, TMR pillars 325, layer(s) 330 of hard mask material, and sheet(s) 308 may be covered with one or more sheets 335 of low temperature oxide (LTO). A LTO may be an oxide layer processed with a low temperature. The LTO may be any oxide that is an insulator and that may be processed with a low temperature. In some embodiments, the LTO may comprise SiO₂.

Top vias 342 may be patterned into sheet(s) 335 (e.g., LTO sheet(s)). For example, one top via 342 per TMR pillar 325 may be patterned into sheet(s) 335 (e.g., LTO) to provide access to the tops of TMR pillars 325. Top via(s) 342 may be patterned into sheet(s) using any known technique for patterning a via into an insulator material. One or more layers 340 of a conductive jumper metal may then be patterned on top of sheet(s) 335 and the tops of TMR pillars 325 (through top vias 342) to connect TMR pillars 325 in any of various arrangements. Any known technique for depositing a conductive metal onto an insulator material may be used. The layer(s) of jumper metal may comprise any type of conductive material, such as Al. The one or more layers of the conductive jumper metal may be deposited such that a second surface (e.g., top surface) of the TMR pillars is in direct contact with the layer(s) of jumper metal.

As a result of the conductive layers (e.g., metal substrate layer(s) 310, conductive fillings of via(s) 315, cushion pad(s) 320, TMR pillar(s) 325, layer(s) 340 of jumper metal) provided in structure 300, TMR pillars 325 may be connected. That is, a voltage source may be applied to one of the conductive layers, and current may then flow through the structure via metal substrate(s) 315, the conductive fillings of bottom via(s) 315, cushion pad(s) 320, and jumper metal layer(s) 340. FIG. 3A shows TMR pillars 325 as being connected in a series arrangement.

Jumper metal layer(s) 340 and layer(s) 335 (e.g., LTO layer(s)) may then be covered with one or more layers 345 of an insulation material (e.g., SiO₂) by a high density plasma (HDP) process. One or more passivation layers 348 may then be added onto layer(s) 335. Passivation layer(s) 348 may be an insulation material (e.g., SiO₂), for example. Passivation layer(s) 348 may protect the internal parts of structure 300 from damage, corrosion, and/or exposure to the surrounding environment.

FIG. 3B shows a top view of an example connection arrangement 350 of a structure (e.g., structure 300 of FIG. 3A) having one TMR pillar 325 per cushion pad 320 and multiple bottom vias 315 per cushion pad 320, where TMR pillars 325 are connected in series. As discussed above with respect to FIG. 3A, TMR pillars 325 may be connected via metal substrate layer(s) 310, the conductive fillings of bottom via(s) 315, cushion pad(s) 320, and jumper metal layer(s) 340 (which connect to the top of TMR pillars 325 through top vias 342). The top view in FIG. 3B shows five bottom vias 315 (only three of which can be seen the side view of FIG. 3A) per cushion pad 320.

FIG. 3C shows a top view of an example connection arrangement 375 of a structure (e.g., structure 300 of FIG. 3A) having one TMR pillar 325 per cushion pad 320 and multiple bottom vias 315 per cushion pad 320, where some TMR pillars 325 are connected in parallel. As discussed above with respect to FIG. 3A, TMR pillars 325 may be connected via metal substrate layer(s) 310, the conductive fillings of bottom via(s) 315, cushion pad(s) 320, and jumper metal layer(s) 340 (which connect to the top of TMR pillars 325 through top vias 342). FIG. 3C shows that sets of TMR pillars may be connected in parallel, with the parallel sets then connected in series. For example, FIG. 3C shows TMR pillars 325 connected in parallel in sets 380, sets 380 then being connected in series. By connecting TMR pillars 325 in different series and/or parallel arrangements, an overall resistance of structure 300 may be modified. For example, a parallel connection of two TMR pillars 325 may result in a resistance of a set 380 of the two TMR pillars 325 that is one half the resistance of a single TMR pillar 325. It may be useful to modify the resistance of an overall connection arrangement in a structure 300, such as when structure 300 is a magnetic field sensing element to be used in a branch of a bridge (e.g., a half bridge or Wheatstone bridge) and a specific resistance is desired to minimize any signaling offsets from other branches of the bridge. An overall resistance of a structure 300 may be modified with different connection arrangements without having to change the layout of the TMR pillars in structure 300. Only the connection scheme of the jumper metal layers (e.g., jumper metal layer(s) 340) would need to be modified to adjust the connection arrangement within a structure 300.

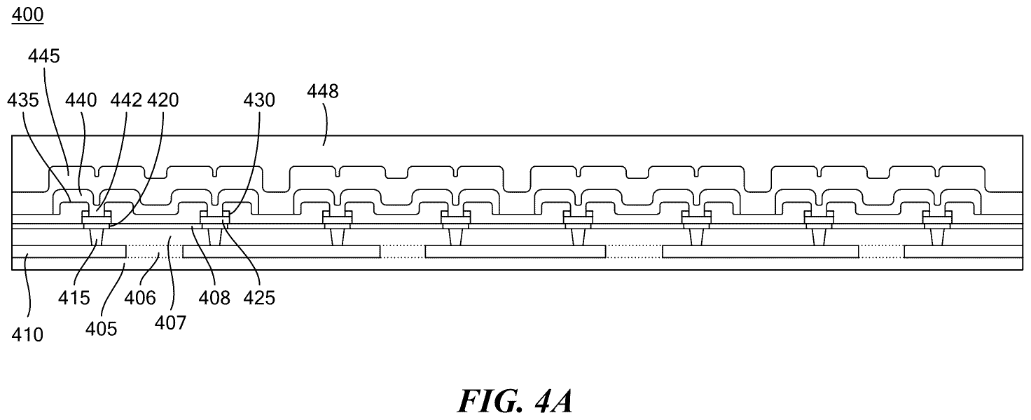

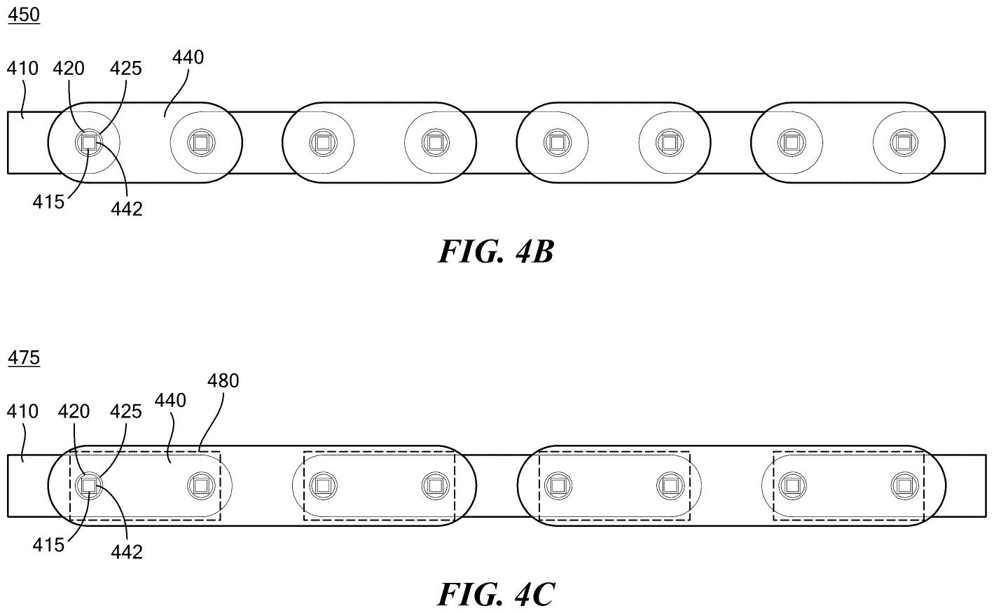

FIG. 4A shows a cross section of an example structure 400 having one TMR pillar 425 per cushion pad 420 and one bottom via 415 per cushion pad 420. Structure 400 may be constructed as discussed above for structure 300 in FIG. 3A, but with smaller cushion pads (e.g., smaller in a lateral dimension), smaller TMR pillars (e.g., smaller in a lateral dimension), smaller top vias (e.g., smaller in a lateral dimension), and a single bottom via per cushion pad. For example, one or more sheets 405 may be constructed in the same manner as sheet(s) 305, one or more sheet(s) 406 may be constructed in the same manner as sheet(s) 306, and one or more layers 410 of metal substrate may be constructed in the same manner as one or more layers 310 of metal substrate. One or more sheets 407 may be constructed in the same manner as sheet(s) 307, and bottom via(s) 415 may be constructed in the same manner as bottom via(s) 315 and filled with a conductive material as discussed for via(s) 315, except that only one bottom via 415 may be constructed for each cushion pad and TMR pillar. One or more sheets 408 may be constructed in the same manner as sheet(s) 308. Cushion pad(s) 420 may be constructed in the same manner as cushion pad(s) 320, but with a smaller lateral dimension than cushion pad(s) 320, and TMR pillar(s) 425 may be constructed in the same manner as TMR pillar(s) 325, but with a smaller lateral dimension than TMR pillar(s) 325. TMR pillars 425 may be patterned and etched using a hard mask material 430 in the same manner as patterning and etching TMR pillars 325 using layer(s) 330 of hard mask material except that TMR pillars 425 may be patterned and etched to have a smaller lateral dimension than TMR pillars 325.

As with structure 300, one or more sheets 435 of LTO may cover TMR pillars 425, hard mask layer(s) 430, and sheet(s) 408. Top vias 442 may then be patterned into sheet(s) 435 in the same manner as discussed for top vias 342 for structure 300, to provide access to the tops of the TMR pillars. One or more layers 440 of a jumper metal may then be patterned on top of sheet(s) 435 and the tops of TMR pillars 425 (through top vias 442) in same manner as described for the layers 340 of jumper metal added in structure 300, to connect TMR pillars 425 in any of various arrangements. One or more HDP layers 445 and passivation layers 448 may then be added in the same manner as discussed for layers 345 and 348, respectively, of structure 300.

FIG. 4A shows structure 400 as having a single bottom via 415 per TMR pillar 425, rather than an array of bottom vias (e.g., five bottom vias) per TMR pillar as shown for structure 300 in FIGS. 3A-3C. Additionally, the TMR pillars shown in example structure 400 may be smaller in a lateral dimension than the TMR pillars shown for example structure 300. Example structures 300 and 400 demonstrate that TMR pillars with a wide range of lateral dimensions may be incorporated into structures, by varying lateral dimensions of the cushion pads, TMR pillars, and top vias, and by varying the number of bottom vias per cushion pad.

As with structure 300, TMR pillars 425 of structure 400 may be connected in various arrangements, with TMR pillars 425 connected in series and/or with TMR pillars 425 connected in parallel. FIG. 4B shows a top view of an example connection arrangement 450 of a structure (e.g., structure 400 of FIG. 4A) having one TMR pillar 425 per cushion pad 420 and one bottom via 415 per cushion pad, where TMR pillars 425 are connected in series. That is, TMR pillars 425 may be connected in series via metal substrates layer(s) 410, the conductive fillings of bottom via(s) 415, cushion pad(s) 420, and jumper metal layer(s) 440 (which connect to the top of TMR pillars 425 through top vias 442). The top view in FIG. 4B shows one bottom via 415 per cushion pad 420.

FIG. 4C shows a top view of an example connection arrangement 475 of a structure (e.g., structure 400 of FIG. 4A) having one TMR pillar 425 per cushion pad 420 and one bottom via 415 per cushion pad, where some of the TMR pillars 425 are connected in parallel. As discussed above with respect to FIG. 4A, TMR pillars 425 may be connected via metal substrate layer(s) 410, the conductive fillings of bottom via(s) 415, cushion pad(s) 420, and jumper metal layer(s) 440 (which connect to the top of TMR pillars 425 though top vias 442). FIG. 4C shows that sets of TMR pillars may be connected in parallel, with the parallel sets then connected in series. For example, FIG. 4C shows TMR pillars 425 connected in parallel in sets 480, sets 480 then being connected in series. By connecting TMR pillars 425 in different series and/or parallel arrangements, overall resistance of structure 400 may be modified. For example, a parallel connection of two TMR pillars 425 may result in a resistance of a set 480 of the two TMR pillars 425 that is one half the resistance of a single TMR pillar 425. It may be useful to modify the resistance of an overall connection arrangement in a structure 400, such as when structure 400 is a magnetic field sensing element to be used in a branch of a bridge (e.g., a Wheatstone bridge) and a specific resistance is desired. Notably, overall resistance of a structure 400 may be modified with different connection arrangements without having to change the layout of the TMR pillars in structure 400. Only the configuration of the jumper metal layers (e.g., jumper metal layer(s) 440) would need to be modified to adjust the connection arrangement within a structure 400.

When constructing a structure, such as structure 400 where only a single bottom via is provided per cushion pad and TMR pillar, the single vias may result in connection paths that have relatively high resistance. As a result, it may be desirable to connect these cushion pads and TMR pillars in a parallel connection arrangement to reduce resistance of the connections. It may also be desirable to use a parallel connection arrangement for such a structure, because such a parallel connection arrangement would provide for an alternative conduction path should a conduction path through one of the TMR pillars, cushion pads, or vias fail. That is, the parallel connection provides redundancy that would not exist in a connection arrangement where TMR pillars each have only a single via and are only connected in series.

As previously discussed, a lateral dimension of a TMR pillar 425 in structure 400 may be smaller than a lateral dimension of a TMR pillar 325 in structure 300. Thus, example structures 300 and 400 demonstrate that TMR pillars with a wide range of lateral dimensions may be incorporated into structures by varying lateral dimensions of the pad cushions, TMR pillars, and top vias, and by varying the number of bottom vias, per cushion pad. However, there may be limits to how small top and bottom vias can be made in a lateral dimension. That limit may be, for example, approximately 0.2 microns. It may not be possible to make TMR pillars that are smaller in a lateral dimension than the lateral dimension of a via. As a result, a limit in how small a via may be made (in a lateral dimension) may also limit how small a TMR pillar may be made (in a lateral dimension). A structure (e.g., structure 400) can be constructed with a single via below and above each TMR pillar, but it may not be possible to make a TMR pillar smaller in a lateral dimension than the lateral dimension of that single via. The lateral dimension of a via therefore becomes a limiting factor in how small a TMR pillar can be made.

It may be desirable to reduce a lateral dimension of TMR pillars to a size smaller than the lateral dimension of a via. It may also be desirable to provide multiple conduction paths through multiple vias to small TMR pillars, to reduce resistance of the conduction paths and to provide redundancy in case a conduction path should fail. Embodiments of the present disclosure provide structures, methods, and techniques for reducing a lateral dimension of TMR pillars. Embodiments of the present disclosure also provide structures, methods, and techniques for reducing a resistance of connection paths and increasing redundancy in a structure.

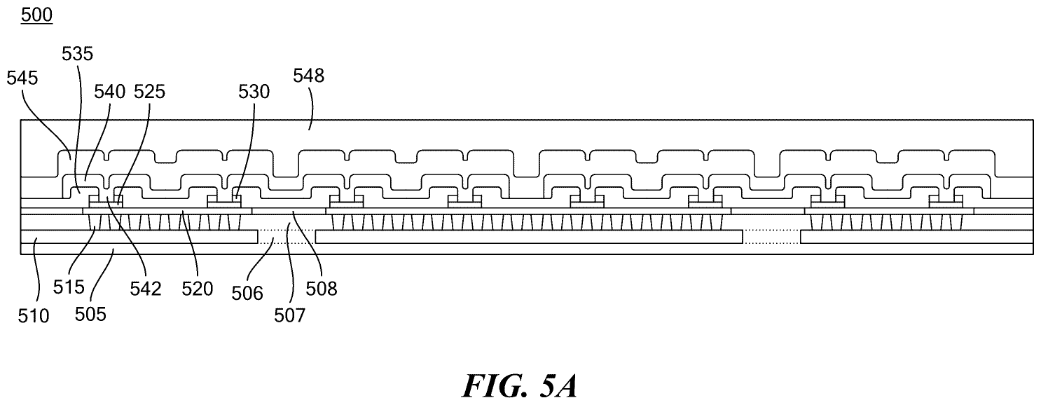

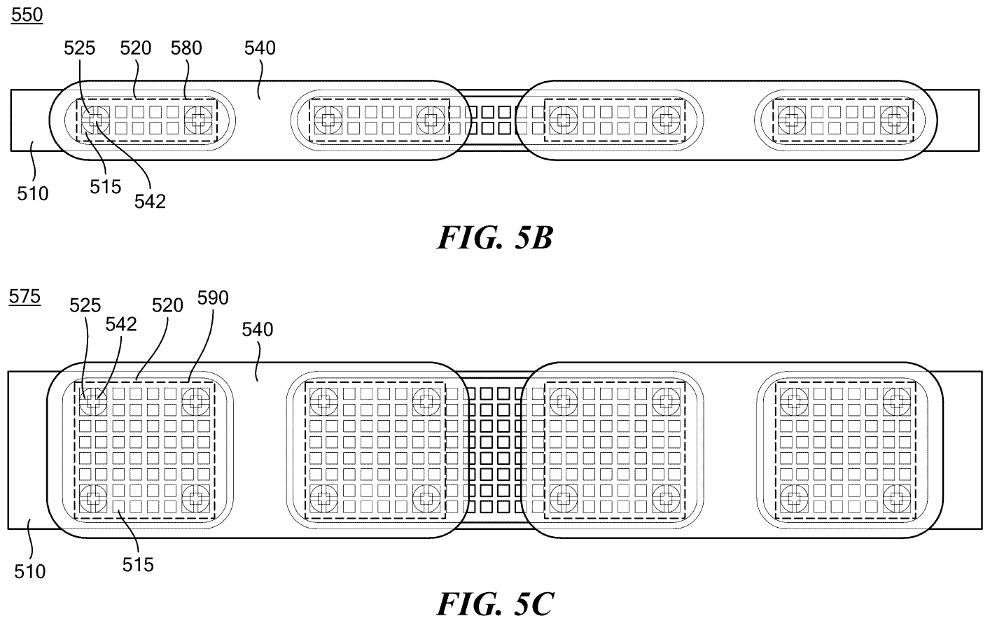

FIG. 5A shows a cross section of an example structure 500 having multiple TMR pillars 525 per cushion pad 520 and multiple vias 515 under cushion pads 520, consistent with embodiments of the present disclosure. Structure 500 may be constructed as discussed above for structure 300 in FIG. 3A, but with larger (in a lateral dimension) cushion pads 520 with larger arrays of bottom vias, and with multiple TMR pillars 525 constructed on each cushion pad 520. For example, one or more sheets 505 may be constructed in the same manner as sheet(s) 305, one or more sheet(s) 506 may be constructed in the same manner as sheet(s) 306, and one or more layers 510 of metal substrate may be constructed in the same manner as metal substrate(s) 310. One or more sheets 507 may be constructed in the same manner as sheet(s) 307, and bottom via(s) 515 may be constructed in the same manner as bottom via(s) 315 and filled with a conductive material as discussed for via(s) 315. However, because cushion pad 520 is larger (in a lateral dimension) than the cushion pads described with respect to structure 300, it is possible to create a greater number of vias under the cushion pads in structure 500. In the cross section of example structure 500 shown in FIG. 5A, thirty-six bottom vias 515 patterned into sheet(s) 507 can be seen.

One or more sheets 508 may be constructed in the same manner as sheet(s) 308. Cushion pad(s) 520 may be constructed in the same manner as cushion pad(s) 320, but with a larger lateral dimension than cushion pad(s) 320. TMR pillar(s) 525 may be constructed in the same manner as TMR pillar(s) 325. However, the TMR pillars in structure 500 may be constructed on larger (laterally) cushion pads, allowing TMR pillars to be constructed that are large or small in a lateral dimension. Additionally, as shown in FIG. 5A, multiple TMR pillars 525 may be constructed on the same cushion pad 520 in structure 500. TMR pillars 525 may be patterned using a hard mask material 530 in the same manner as patterning TMR pillars 325 using layer(s) 330 of hard mask material. However, in structure 500 TMR pillars 525 may be patterned and etched such that multiple TMR pillars are provided on the same cushion pad 520. In the cross section of example structure 500 shown in FIG. 5A, three cushion pads 520 can be seen, one with two TMR pillars constructed on top of it, one with four TMR pillars constructed on top of it, and another with two TMR pillars constructed on top of it. In some embodiments, TMR pillars 525 may be patterned and etched to be smaller in a lateral dimension than the lateral dimension of a bottom via 515. That is, because cushion pad 520 is larger in a lateral dimension than the lateral dimension of a via, a TMR pillar 525 constructed on top of the cushion pad can be smaller in a lateral dimension than the lateral dimension of the via.

As with structure 300, one or more sheets 535 of LTO may cover TMR pillars 525, hard mask layer(s) 530, and sheet(s) 508. Top vias 542 may then be patterned into sheet(s) 535 in the same manner as discussed for top vias 342 for structure 300, to provide access to the tops of the TMR pillars. Layers 540 of a jumper metal may then be patterned on top of sheet(s) 535 and the tops of TMR pillars 525 (through top vias 542) in the same manner as described for layers 340 of jumper metal added in structure 300, to connect TMR pillars 525 in any of various arrangements. One or more layers 545 (e.g., HDP layers) and passivation layers 548 may then be added in the same manner as discussed for layers 345 and 348, respectively, of structure 300.

In some embodiments, structure 500 may be constructed such that a first surface (e.g., bottom surface) of one or more TMR pillars is in direct contact with a cushion pad and such that at second surface (e.g., top surface) of the one or more TMR pillars is in direct contact with layer(s) of the jumper metal. In some embodiments, structure 500 may be constructed such that a surface (e.g., bottom surface) of each of at least two TMR pillars is in direct contact with a first side (e.g., top side) of a cushion pad, and such that an area of the first side (e.g., top side) of the cushion pad is greater than a combined area of the first surfaces of the at least two TMR pillars. In some embodiments, structure 500 may be constructed such that each of at least two TMR pillars is in direct contact with a first side of a cushion pad, and a second side of the cushion pad is in direct contact with a plurality of bottom vias, each of the bottom vias being filled with a conductive material for electrically connecting the cushion pad to one or more layers of a metal substrate.

Constructing structures (e.g., structure 500) with larger cushion pads (in a lateral dimension) has advantages. For example, as shown in FIG. 5A, a greater number of bottom vias may be provided for connecting the cushion pads to the metal substrates. This greater number of bottom vias may provide for reduced resistance in conduction paths through the structure. Moreover, multiple TMR pillars may be constructed on each cushion pad and connected in parallel, thus further reducing the resistance in the conduction paths through the structure. Providing a greater number of bottom vias also provides redundancy in the conduction path, should any of the vias fail. Similarly, providing more than one TMR pillars on a cushion pad, connected in parallel, provides redundancy in the conduction path, should any of the TMR pillars fail. Providing a larger cushion pad may also allow for construction of TMR pillars that are smaller (in a lateral dimension) than a bottom via (in a lateral dimension), because the cushion pads on which the TMR pillars are constructed may be larger (in a lateral dimension) than the bottom via (in a lateral dimension).

As with structure 300, TMR pillars 525 of structure 500 may be connected in various arrangements, with TMR pillars 525 connected in series and/or with TMR pillars 525 connected in parallel. FIG. 5B shows a top view of an example connection arrangement 550 of a structure (e.g., structure 500 of FIG. 5A) having two TMR pillars 525 on one cushion pad 520, four TMR pillars 525 on another cushion pad 520, and two TMR pillars 525 on yet another cushion pad 520. In example connection arrangement 550, one of the cushion pads 520 is connected to layer(s) 510 of metal substrate through sixteen bottom vias 515 (conductively filled), one of the cushion pads 520 is connected to layer(s) 510 of metal substrate through forty-four bottom vias 515 (conductively filled), and another of the cushion pads 520 is connected to layer(s) 510 of metal substrate through sixteen bottom vias 515 (conductively filled). As discussed previously, TMR pillars 525 may be connected via layer(s) 510 of metal substrate, the conductive fillings of bottom via(s) 515, cushion pad(s) 520, and jumper metal layer(s) 540 (which connect to the top of TMR pillars 525 through top vias 542). In connection arrangement 550, some of the TMR pillars 525 are connected in parallel. For example, TMR pillars 525 are connected in parallel in sets 580, sets 580 then being connected in series. By connecting TMR pillars 525 in different series and/or parallel arrangements, overall resistance of structure 500 may be modified, which may be useful when a specific resistance is desired (e.g., for optimizing offset for use as a branch in a bridge). Parallel connections may also lower resistance of conductive paths through structure 500, which may generally improve the efficiency and/or integrity of structure 500. For example, including several conductive bottom vias per cushion pad and TMR pillar may make the contact between the metal substrates and TMR pillars more reliable, thereby increasing yield of reliable structures in the manufacturing process.

FIG. 5C shows a top view of an example connection arrangement 575 of a structure (e.g., structure 500 of FIG. 5A) having four TMR pillars 525 on one cushion pad 520, eight TMR pillars 525 on another cushion pad 520, and four TMR pillars 525 on yet another cushion pad 520. In example connection arrangement 575, one of the cushion pads 520 is connected to layer(s) 510 of metal substrate through sixty-four bottom vias 515 (conductively filled), one of the cushion pads 520 is connected to layer(s) 510 of metal substrate through one hundred seventy-six vias 515 (conductively filled), and another of the cushion pads 520 is connected to layer(s) 510 of metal substrate through sixty-four bottom vias (515) conductively filled). As discussed previously, TMR pillars 525 may be connected via layer(s) 510 of metal substrate, the conductive fillings of bottom via(s) 515, cushion pad(s) 520, and jumper metal layer(s) 540 (which connect to the top of TMR pillars 525 through top vias 542). In connection arrangement 575, some of the TMR pillars 525 are connected in parallel. For example, TMR pillars 525 are connected in parallel in sets 590, sets 590 then being connected in series. By connecting TMR pillars 525 in different series and/or parallel arrangements, overall resistance of structure 500 may be modified, which may be useful when a specific resistance is desired (e.g., for use as a branch in a bridge). For example, connection arrangement 575 may have lower resistance in the TMR pillars 525 than connection arrangement 550, because connection arrangement 575 has sets 590 with four TMR pillars 525 in parallel, while connection arrangement 550 has sets 580 with two TMR pillars 525 in parallel.

A person of ordinary skill in the art would recognize that the techniques discussed above with respect to FIGS. 5A-5C may be extended to provide any number of TMR pillars per cushion pad, in any number of arrangements. Varying parallel and/or series connections of TMR pillars and a number of TMR pillars connected in parallel may allow construction of a structure that has a precise amount of desired TMR resistance, for use in a sensor device.

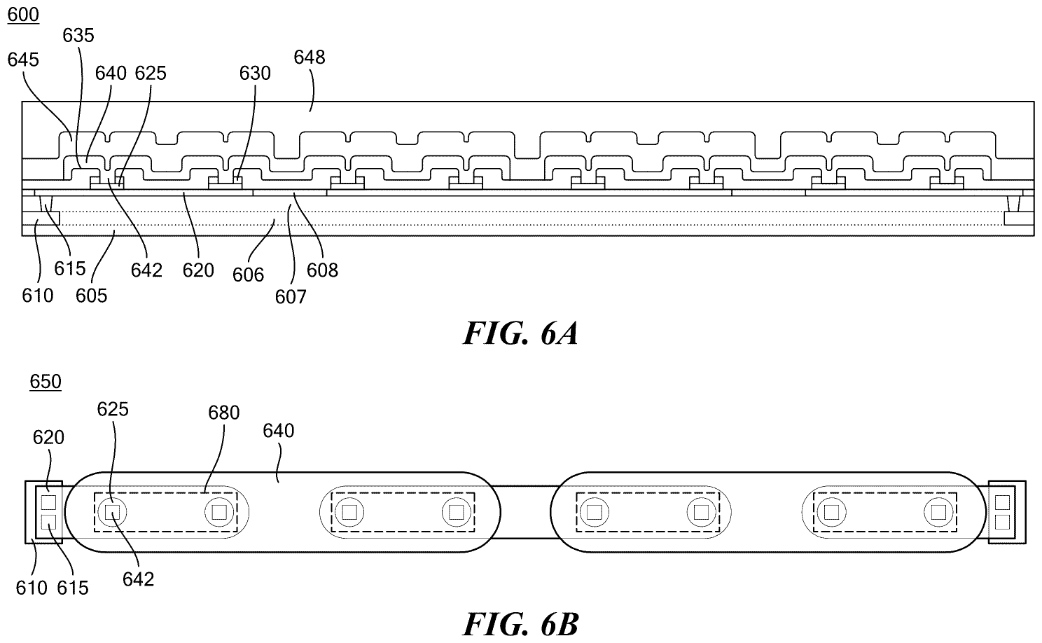

In some embodiments, a structure may be constructed with cushion pads that have a large lateral dimension and with bottom vias connected at ends of the cushion pads, to free up space in the structure beneath the cushion pads. For example, FIG. 6A shows a cross section of an example structure 600 having multiple TMR pillars 625 per cushion pad 620 and bottom vias 615 at ends of some of the cushion pads. Structure 600 may be constructed as discussed above for structure 500, except that bottom vias may only be provided at the ends of some of the cushion pads and the metal substrate(s) connected to the cushion pads may not extend along the entire lateral dimension of the cushion pads. For example, one or more sheets 605 may be constructed in the same manner as sheet(s) 505. One or more sheet(s) 606 may be constructed in the same manner as sheet(s) 606, and one or more layers 610 of metal substrate may be constructed in the same manner as layer(s) 510 of metal substrate, except that these layer(s) 610 of metal substrate may not extend along the entire lateral dimension of the cushion pads in structure 600. In some embodiments, as shown in FIG. 6A, the layer(s) 610 of metal substrate may only extend along the lateral dimension of a cushion pad enough to allow for connection of the metal substrate through some smaller number of bottom vias.

One or more sheets 607 may be constructed in the same manner as sheet(s) 507, and bottom via(s) 615 may be constructed in the same manner as bottom via(s) 515 and filled with a conductive material as discussed for via(s) 515. However, as shown in FIG. 6A, a smaller number of bottom via(s) 615 may be used here to connect layer(s) 610 of metal substrate to a cushion pad 620, as compared to structure 500, and metal substrate layer(s) 610 may not extend far along the lateral dimension of a cushion pad 620. In the cross section of example structure 600 shown in FIG. 6A, two bottom vias 615 patterned into sheet(s) 607 can be seen.

One or more sheets 608 may be constructed in the same manner as sheet(s) 508. Cushion pad(s) 620 may be constructed in the same manner as cushion pad(s) 520. However, some cushion pad(s) 620 may be extended a bit longer in a lateral dimension than cushion pad(s) 520 to connect a cushion pad 620 with layer(s) 610 of metal substrate through one or more bottom vias 615. TMR pillar(s) 625 may be constructed in the same manner as TMR pillar(s) 525, and as discussed with respect to structure 500, multiple TMR pillars 625 may be constructed on the same cushion pad 620. TMR pillars 625 may be patterned and etched using a hard mask material 630 in the same manner as patterning and etching TMR pillars 525 using hard mask material 530.

As with structure 500, one or more sheets 635 of LTO may cover TMR pillars 625, hard mask layer(s) 630, and sheet(s) 608. Top vias 642 may then be patterned and etched into sheet(s) 635 in the same manner as discussed for top vias 542 for structure 500, to provide access to the tops of the TMR pillars. Layer(s) 640 of jumper metal may then be patterned on top of sheet(s) 635 and the tops of TMR pillars 625 (through top vias 642) in the same manner as described for layer(s) 540 of jumper metal added in structure 500, to connect TMR pillars 625 in any of various arrangements. One or more HDP layers 645 and passivation layers 648 may then be added in the same manner as discussed for layers 545 and 548, respectively, of structure 500.

In some embodiments, structure 600 may be constructed such that a first surface (e.g., bottom surface) of one or more TMR pillars is in direct contact with a cushion pad and such that at second surface (e.g., top surface) of the one or more TMR pillars is in direct contact with layer(s) of the jumper metal. In some embodiments, structure 600 may be constructed such that a surface (e.g., bottom surface) of each of at least two TMR pillars is in direct contact with a first side (e.g., top side) of a cushion pad. In some embodiments, structure 600 may be constructed such that an area of the first side (e.g., top side) of the cushion pad is greater than a combined area of the first surfaces of the at least two TMR pillars. In some embodiments, structure 600 may be constructed such that each of at least two TMR pillars is in direct contact with a first side of a cushion pad, and a second side of the cushion pad is in direct contact with one or more bottom vias, each of the one or more bottom vias being filled with a conductive material for electrically connecting the cushion pad to one or more layers of a metal substrate. In some embodiments, structure 500 may be constructed such that a first side of a cushion pad is in direct contact with a bottom surface of at least two TMR pillars, and a second side of the cushion pad is in direct contact with one or more bottom vias.

The arrangement of materials in structure 600 may have advantages. For example, structure 600 may free up space underneath the cushion layers 620 and TMR pillars 625 as compared to structure 500. Although not shown, one or more additional layers of metal substrate may be passed under one or more cushion pads 620 and TMR pillars 625. These one or more additional layers of metal substrate may, in some embodiments, not be connected to layer(s) 610 of metal substrate or to the general conduction path through TMR pillars in structure 600. In some embodiments, a current may be passed through these one or more additional layers of metal substrate. This current may be a constant amount of current, or may be varied by an external controller. The current passing through these one or more additional layers of metal substrate may generate a magnetic field, which may repin one or more layers of the TMR pillars 625 to be more sensitive to a particular orientation of magnetic field or amplitude of magnetic field. Another possible advantage of structure 600 over structure 500 is that, by moving the bottom vias 615 to an outer edge of the cushion pads 620 and away from TMR pillars 625, bottom vias 615 may not affect the flatness or smoothness of the cushion pad in the locations where TMR pillars 625 are constructed, allowing for better performance of the TMR pillars.

As with structure 500, TMR pillars 625 of structure 600 may be connected in various arrangements, with TMR pillars 625 connected in series and/or with TMR pillars 625 connected in parallel. FIG. 6B shows a top view of an example connection arrangement 650 of a structure (e.g., structure 600 of FIG. 6A) having multiple TMR pillars 625 per cushion pad 620 and bottom vias (conductively filled) 615 at ends of some cushion pads 620, consistent with embodiments of the present disclosure. Example connection arrangement 650 includes three cushion pads 620, one of which has two TMR pillars 625 constructed on it, one of which has four TMR pillars 625 constructed on it, and another of which has two TMR pillars 625 constructed on it. In example connection arrangement 650, one of the cushion pads 620 is connected to layer(s) 610 of metal substrate through two bottom vias 615, and another of the cushion pads is connected to another layer(s) 610 of metal substrate through two additional bottom vias 615. The middle cushion pad is not connected to a metal substrate by bottom vias, but is connected in series with the other two cushion pads by jumper metal layer(s) 640. That is, TMR pillars 625 may be connected via metal substrate layer(s) 610, the conductive fillings of bottom via(s) 615, cushion pad(s) 620, and jumper metal layer(s) 640 (which connect to the top of TMR pillars 625 through top vias 642). In connection arrangement 650, some of the TMR pillars 625 are connected in parallel. For example, TMR pillars 625 are connected in parallel in sets 680, sets 680 then being connected in series. As previously discussed, by connecting TMR pillars 625 in different series and/or parallel arrangements, overall resistance of structure 600 may be modified, which may be useful when a specific resistance is desired (e.g., for optimizing offset for use as a branch in a bridge). As also previously discussed, parallel connections may lower resistance of conductive paths through structure 600, which may generally improve the efficiency and/or integrity of structure 600.

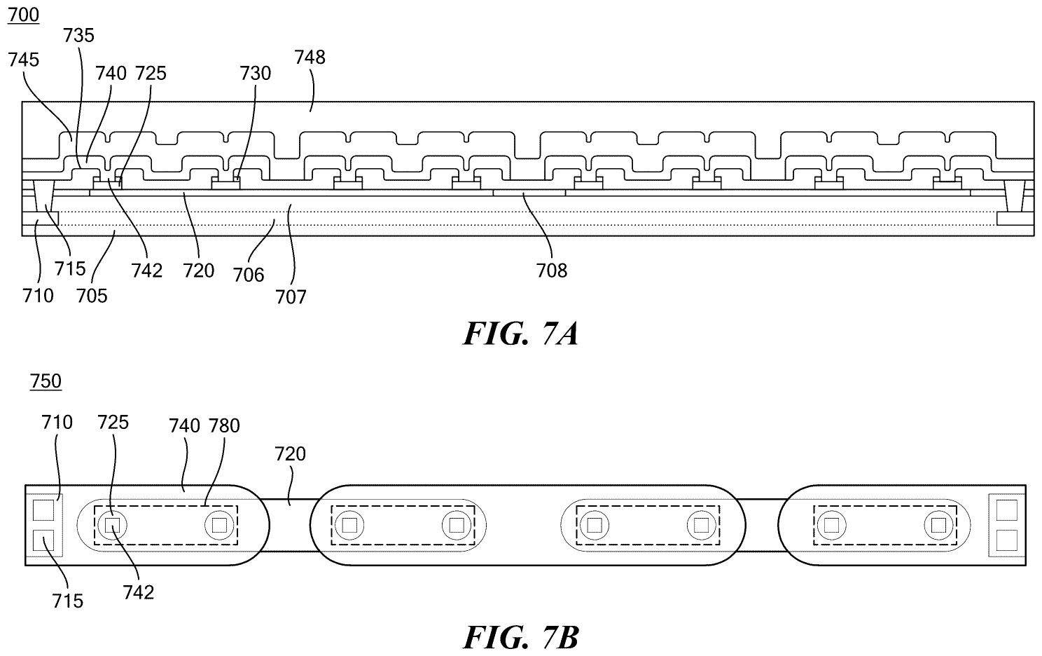

In some embodiments, a structure may be constructed with cushion pads that do not directly connect with layers of a metal substrate through bottom vias, to even further free up space in the structure beneath the cushion pads. For example, FIG. 7A shows a cross section of an example structure 700 having multiple TMR pillars 725 per cushion pad 720. Structure 700 may be constructed in a manner like the manner discussed for structure 600, except that in structure 700 bottom vias no longer connect one or more layers of metal substrate to cushion pads. Rather, in structure 700, vias may connect one or more layers of metal substrate directly to one or more layers of a jumper metal, and the jumper metal may then be used to connect the cushion pads and TMR pillars together.

For example, one or more sheets 705 may be constructed in the same manner as sheet(s) 605. One or more sheets 706 may be constructed in the same manner as sheet(s) 606, and one or more layers 710 of metal substrate may be constructed in the same manner as metal substrate(s) 610. One or more sheets 707 may be constructed in the same manner as sheet(s) 607. One or more sheets 708 may be constructed in the same manner as sheet(s) 608. Cushion pad(s) 720 may be constructed in the same manner as cushion pad(s) 620. In the cross-section of example structure 700 shown in FIG. 7A, two cushion pads 720 can be seen, each supporting four TMR pillars, which is different than as shown for structure 600.

TMR pillar(s) 725 may be constructed in the same manner as TMR pillar(s) 625, and as discussed with respect to structure 600, multiple TMR pillars 725 may be constructed on the same cushion pad 720. TMR pillar(s) 725 may be patterned and etched using sheet(s) 730 of hard mask material in the same manner as patterning and etching TMR pillars 625 using hard mask material 630. The cross section of example structure 700 in FIG. 7A shows that four TMR pillars 725 have been etched onto each cushion pad 720 in example structure 700.

As with structure 600, one or more sheets 735 of LTO may cover TMR pillar(s) 725, hard mask layer(s) 730, and sheet(s) 708. Top via(s) 742 may then be patterned and etched into sheet(s) 735 in the same manner as discussed for top vias 642 for structure 600, to provide access to the tops of the TMR pillars. One or more vias 715 may also be patterned and etched to provide access through the sheets of structure 700 to layer(s) 710 of metal substrate. Via(s) 715 may then be filled with a conductive material, such as described for bottom via(s) 615 of structure 600. Alternatively, via(s) 715 may be filled with the conductive material of one or more layers 740 of jumper metal when the jumper metal is patterned.

Layer(s) 740 of jumper metal may then be patterned on top of sheet(s) 735 and the tops of TMR pillars 725 (through top vias 742) in the same manner as described for layer(s) 640 of jumper metal added in structure 600, to connect TMR pillars 725 in any of various arrangements. In some embodiments, patterning of layer(s) 740 of jumper metal may also fill via(s) 715 with the conductive metal of layer(s) 740. One or more HDP layers 745 and layers 748 of passivation material may then be added in the same manner as discussed for layers 645 and 648, respectively, of structure 600.

In some embodiments, structure 700 may be constructed such that a first surface (e.g., bottom surface) of one or more TMR pillars is in direct contact with a cushion pad and such that at second surface (e.g., top surface) of the one or more TMR pillars is in direct contact with layer(s) of the jumper metal. In some embodiments, structure 700 may be constructed such that a surface (e.g., bottom surface) of each of at least two TMR pillars is in direct contact with a first side (e.g., top side) of a cushion pad. In some embodiments, structure 700 may be constructed such that an area of the first side (e.g., top side) of the cushion pad is greater than a combined area of the first surfaces of the at least two TMR pillars.

The arrangement of materials in structure 700 may have advantages. For example, structure 700 may free up even more space underneath the cushion layers 720 and TMR pillars 725, as compared with structure 600. Although not shown, one or more additional layers of metal substrate may be passed under one or more cushion pads 720 and TMR pillars 725. These additional one or more layers of metal substrate may, in some embodiments, not be connected to layer(s) 710 of metal substrate or to the general conduction path through TMR pillars in structure 700. In some embodiments, a current may be passed through these one or more additional layers of metal substrate. The current may be a constant amount of current, or may be varied by an external controller. The current passing through these one or more additional layers of metal substrate may generate a magnetic field, which may repin one or more layers of the TMR pillars 725 to be more sensitive to a particular orientation of magnetic field or amplitude of magnetic field. Another possible advantage of structure 700 over structure 600 is that, by removing vias 615 and instead using vias 715, which do not connect directly to the cushion pads 720, the flatness or smoothness of the cushion pads 720 may not be affected by via connections, which may allow for better performance of the TMR pillars.

As with structure 600, structure 700 includes TMR pillars 725 that may be connected in various arrangements, with TMR pillars 725 connected in series and/or with TMR pillars 725 connected in parallel. FIG. 7B shows a top view of an example connection arrangement 750 of a structure (e.g., structure 700 of FIG. 7A) having multiple TMR pillars 725 per cushion pad 720 and vias 715 (conductively filled) that directly connect one or more layers 710 of metal substrate to one or more layers 740 of jumper metal, without any direct connection of vias 715 to cushion pads 720. Example connection arrangement 750 includes two cushion pads 720, each of which has four TMR pillars 725 constructed on it. In example connection arrangement 750, TMR pillars 725 may be connected via metal substrate layer(s) 710, the conductive fillings of via(s) 715, jumper metal layer(s) 740 (which connect to via(s) 715 and the tops of TMR pillars 725 through top vias 742), and cushion pad(s) 720. In connection arrangement 750, some of the TMR pillars 725 are connected in parallel. For example, TMR pillars 725 are connected in parallel in sets 780, sets 780 then being connected in series. As previously discussed, by connecting TMR pillars 725 in different series and/or parallel arrangements, overall resistance of structure 700 may be modified, which may be useful when a specific resistance is desired (e.g., for optimizing offset for use as a branch in a bridge). As also previously discussed, parallel connections may lower resistance of conductive paths through structure 700, which may generally improve the efficiency and/or integrity of structure 700.

Example structures and connection arrangements with multiple TMR pillars on a cushion pad have been described with respect to FIGS. 5A-7B. However, the disclosure should not be limited to these examples. A person of ordinary skill in the art would recognize that many different structures comprising multiple TMR pillars on a cushion pad may be constructed based on the concepts, methods, and techniques discussed above with respect to FIGS. 5A-7B, and those different structures should be considered to be within the scope of the disclosure herein.

As previously discussed, it may be challenging to construct a structure with a TMR pillar that is smaller in a lateral dimension than the lateral dimension of a bottom via. The structures, methods, and techniques discussed with respect to FIGS. 5A-7B provide solutions to that problem, by providing cushion pads that are larger in a lateral dimension and that can accommodate multiple TMR pillars and connections to multiple vias. However, another possible limiting factor in how small (laterally) TMR pillars can be constructed in a structure is how small (laterally) the top vias (e.g., top vias 542, 642, 742) can be made. Moreover, small top vias may limit the amount of conductive jumper metal in contact with the top of a TMR pillar, and as a result these connections may have high resistance and heat up or be otherwise prone to failure because of their limited size.

Embodiments discussed herein may be used to solve potential problems with the limited lateral size of top vias in these structures. For example, FIG. 8 shows a diagram of a process 800 for constructing a structure (e.g., structure 861) that utilizes a conductive hard mask to connect a TMR pillar to a top metal. As was described above with respect to FIGS. 3A-7B, the structure may be constructed of several sheets of materials arranged in a stack. The first several sheets of the stack may be constructed in a manner similar to the manner described above with respect to FIGS. 3A-7B. For example, the first (e.g., bottom) one or more sheets 805 of materials in the stack may be constructed of an insulation material (e.g., SiO₂ or SiN), and may, in some embodiments, comprise a Silicon wafer. One or more sheets 806 of insulation material (e.g., SiO₂) with one or more layers 810 of metal substrate may then be stacked atop sheet(s) 805. Metal substrate layer(s) 810 may be patterned into sheet(s) 806, and may be formed of a conductive material, such as Al for example. In the example cross-sections shown in FIG. 8, two layers 810 of metal substrate patterned into sheet(s) 806 can be seen.

One or more sheets 807 of an insulation material (e.g., SiO₂) with one or more bottom vias 815 may be stacked atop sheet(s) 806. Bottom via(s) 815 may be patterned into sheet(s) 807. Bottom via(s) 815 may be filled with a conductive material, such as Tungsten (W) for example. In the cross-sections shown in FIG. 8, two bottom vias 815 patterned into sheet(s) 807 can be seen.

One or more sheets 808 of an insulation material (e.g., SiO₂) with one or more cushion pads 820 may be provided. For example, one or more cushion pads 820 may be stacked atop sheet(s) 807. Cushion pad(s) 820 may be patterned into sheet(s) 808, and may be formed of a conductive material. In some embodiments, cushion pad(s) 820 may be formed of a conductive material with a flat and smooth surface, which may improve performance of a TMR pillar formed on top of the cushion pad and which may improve performance of a conductive interconnection between a TMR pillar and a metal substrate. A cushion pad 820 may comprise, for example, TiN. Alternatively, a cushion pad may comprise Ti, CuN, or W. In the cross-sections shown in FIG. 8, two cushion pads 820 can be seen. One or more cushion pads 820 may be formed so as to be in direct contact with one or more bottom vias 815. Layers of a TMR pillar (see, e.g., FIG. 2) may then be deposited as a TMR structure 825, resulting in a structure 851.

In 880, one or more sheets 830 of a conductive etch stop material and one or more sheets 835 of a conductive hard mask material may be deposited. For example, the conductive etch stop material may be deposited to be in direct contact with the top of TMR structure 825. Sheet(s) 830 of conductive etch stop material may be deposited onto TMR structure 825 and may comprise a conductive material that does not get etched in a hard mask etching process. In some embodiments, sheet(s) 830 of etch stop material may comprise TiN, for example. Sheet(s) 835 of conductive hard mask material may be deposited onto sheet(s) 830 of etch stop material and may comprise a conductive material that does get etched in a hard mask etching process. For example, the conductive hard mark material may be deposited to be in direct contact with the conductive etch stop material. In some embodiments, sheet(s) 835 of conductive hard mask material may comprise Al or CuN. As a result of depositing sheet(s) 830 and sheet(s) 835, structure 852 may be constructed.

In 882, one or more sheets of a photoresist material may be deposited and patterned into photoresist pillars 840 in the shape in which the TMR pillars are going to be patterned, resulting in structure 853.

In 884, layer(s) 835 of conductive hard mask may be etched to form pillars 845 of conductive hard mask in the shape of photoresist pillars 840. The pillars 840 of photoresist may then be lifted off the structure, resulting in structure 854. The pillars 845 of conductive hard mask each comprise one or more conductive layers of material.

In 886, ion beam etching may be performed on the structure to form pillars 850 of conductive etch stop material and TMR pillars 855, resulting in structure 856. After ion beam etching, structure 856 may comprise conductive pillars (e.g., four shown in FIG. 8), each conductive pillar having a TMR pillar 855, a conductive pillar 850 of etch stop material, and a pillar 845 of conductive hard mask material.

In 888, one or more sheets 860 of a passivation material may be deposited onto structure 856, covering sheet(s) 808, cushion pad(s) 820, TMR pillar(s) 825, pillars 850 of conductive etch stop, and pillars 845 of conductive hard mask, resulting in structure 857. Sheet(s) 860 of passivation material may comprise an insulation material, for example SiO₂ or SiN. Sheet(s) 860 of passivation material may provide structural support for the conductive pillars, and may protect materials in the structure from corrosion or damage.

in 890, a chemical mechanical polishing and etchback process may be performed to polish and etch sheet(s) 860 of passivation material and pillars 845 of conductive hard mask so that the surface at the top of the structure is flat and so that the tops of pillars 845 of conductive hard mask are exposed, resulting in structure 858.

In 892, one or more layers 865 of a top metal (e.g., a jumper metal) may be deposited and patterned on top of the structure, such that layer(s) 865 of the top metal are connected to the tops of pillars 845 of conductive hard mask, resulting in structure 859. In doing so, TMR pillars 855 are connected to layer(s) 865 of the top metal through the pillar(s) 850 of conductive etch stop and the pillar(s) 845 of conductive hard mask. As previously discussed with respect to FIGS. 3A-7B, a top metal (e.g., jumper metal) may be deposited in various ways to connect the TMR pillars in various arrangements, such as with series and/or parallel connections between the TMR pillars.

In 894, one or more sheets 870 of a second passivation layer may be deposited, and one or more sheets 875 of a third passivation layer may be deposited, resulting in structure 861. Sheet(s) 870 may comprise an LTO (e.g., SiO₂), as previously discussed with respect to FIGS. 3A-7B. Sheet(s) 875 may comprise one or more passivation layers comprising an insulation material (e.g., SiO₂, SiN). Sheet(s) 870 and 875 may provide structural support for materials, and may protect materials in the structure from corrosion or damage.

As can be seen in the example in FIG. 8, by using a conductive etch stop and conductive hard mask, connections between the TMR pillars and the top metal may be constructed to be smaller in a lateral dimension than the lateral dimension of the top vias discussed with respect to FIGS. 3A-7B. This smaller lateral dimension may allow smaller TMR pillars to be constructed in a structure (e.g., structure 861). Moreover, process 800 may allow the conductive interface (e.g., through pillar 850 of conductive etch stop material and pillar 845 of conductive hard mask) in a structure (e.g., structure 861) to have the same width as the top of the TMR pillar, taking advantage of the full surface area of the top of the TMR pillar. Additionally, because the top surface of intermediate structure 858 is flat and smooth in process 800, it may be easier to apply layer(s) 865 of top metal and sheet(s) 870 and 875. For example, the process previously described with respect to FIGS. 3A, 4A, 5A, 6A, and 7A may result in rippling of the surfaces of sheet(s) 730, 735, and 740, which may make it harder to deposit a sheet on any of these sheets and which may generally reduce the structural integrity of these structures. By contrast, as can be seen in structures 858, 859, and 861 of FIG. 8, corresponding sheets and layers in process 800 are relatively flat and smooth, which may result in a structure 861 that is easier to manufacture and/or more robust.

As shown in FIG. 8, resulting structure 861 may comprise a first conductive layer (e.g., a cushion pad 820), a second conductive layer (e.g., a pillar 845 of conductive hard mask), and a third conductive layer 865 (e.g., top metal) in direct contact with the second conductive layer. Resulting structure 861 may also comprise at least two TMR pillars 855 in direct contact with the cushion pad, and indirectly coupled to the top metal (e.g., indirectly through a pillar 850 of conductive etch stop material and a pillar 845 of conductive hard mask). In some embodiments, as a result of process 800 described above, a surface area of a top surface of a TMR pillar 855 and a surface area of a bottom surface of a conductive hard mask are approximately the same (see, e.g., resulting structure 861). In some embodiments, the surface area of the bottom surface of the conductive hard mask is no wider than 0.5 microns.

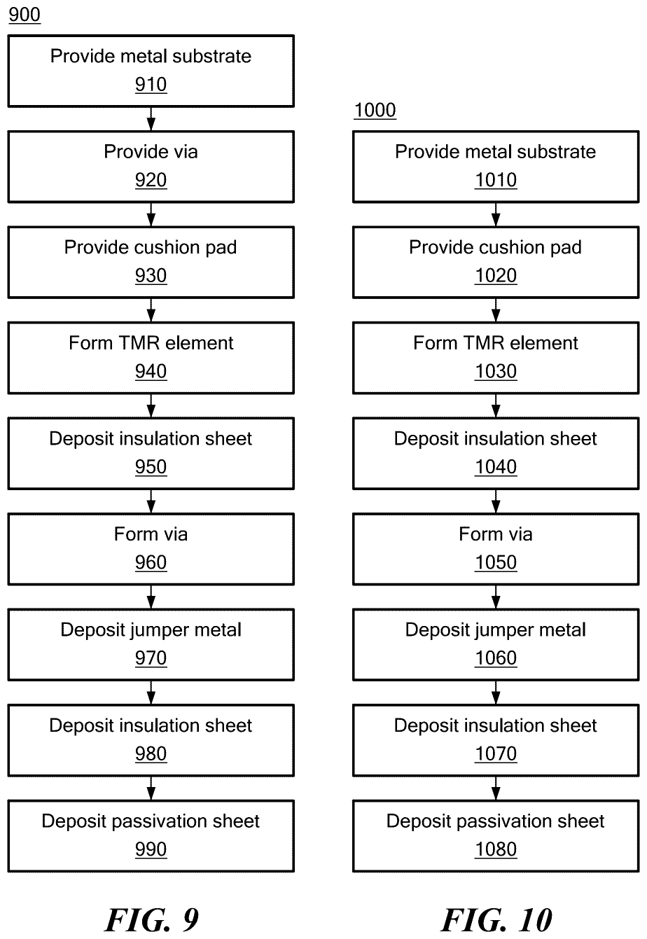

FIG. 9 shows an example process 900 for forming a structure having multiple TMR pillars per cushion pad, consistent with embodiments of the present disclosure. For example, process 900 may be used to construct structure 500 of FIG. 5A or structure 600 of FIG. 6A.

As previously discussed, structures disclosed herein may be formed as a stack of materials. Construction of such a structure may begin with one or more sheets (e.g., sheet(s) 505, sheet(s) 605) of material, such as an insulation material (e.g., SiO₂ or SiN). One or more additional sheets (e.g., sheet(s) 506, sheet(s) 606) of insulation material (e.g., SiO₂ or SiN) may then be constructed and added to the stack, and in 910 one or more layers (e.g., layer(s) 510, layer(s) 610) of metal substrate may be provided in these one or more additional sheets. For example, a metal substrate such as Al may be patterned into the one or more additional sheets.

One or more additional sheets (e.g., sheet(s) 507, sheet(s) 607) of an insulation material (e.g., SiO₂ or SiN) may then be constructed and added to the stack, and in 920 one or more bottom vias (e.g., bottom via(s) 515, bottom via(s) 615) may be provided in these sheets. For example, as previously discussed, these one or more bottom vias may be patterned into the sheets and may be filed with a conductive material, such as W.

One or more additional sheets (e.g., sheet(s) 508, sheet(s) 608) of an insulation material (e.g., SiO₂ or SiN) may then be constructed and added to the stack, and in 930 one or more cushion pads (e.g., cushion pad(s) 520, cushion pad(s) 620) may be provided in these sheets. For example, as previously discussed, these one or more cushion pads may be patterned into the one or more additional sheets and may be formed of a conductive material. In some embodiments, the cushion pad(s) may be formed to have a flat and smooth surface. The one or more cushion pads may be formed of TiN, Ti, CuN, or W, for example.

In 940, one or more TMR elements may be formed. The one or more TMR elements may be TMR pillars (see, e.g., TMR pillar of FIG. 2, TMR pillar(s) 525, TMR pillar(s) 625), as previously discussed. The one or more TMR pillars may be constructed of multiple layers, such as TMR pillar 200 of FIG. 2. As previously discussed, TMR pillars may be constructed by first depositing the layers of the TMR pillars as sheets of materials in a TMR structure that extends across the structure (see, e.g., 825 of FIG. 8). One or more layers of materials may then be applied on top of the TMR structure and patterned onto the TMR structure (see, e.g., 835, 840 of FIG. 8). For example, one or more layers of a hard mask material may be applied on top of the TMR structure. The patterning of the layer(s) of hard mask may then be used to etch (e.g., using photolithography, ion beam etching, etc.) the TMR structure into separate TMR pillars (see, e.g., FIG. 8).

In 950, one or more sheets (e.g., sheet(s) 535, sheet(s) 635) of an insulation material may be deposited. The one or more sheets of insulation material may comprise an oxide layer processed with a low temperature (i.e., a low temperature oxide), such as SiO₂.

In 960, one or more top vias (e.g., top via(s) 542, top via(s) 642) may be patterned into the one or more sheets of insulation material to provide access to the tops of the TMR elements.

In 970, one or more layers (e.g., layer(s) 540, layer(s) 640) of a jumper metal may be patterned on top of the one or more sheets of insulation material and on top of the one or more TMR elements (through the top via(s)) to connect TMR elements together in any of various arrangements (e.g., any of connection arrangements 550, 575, 650). The layer(s) of jumper metal may comprise, for example, Al.

In 980, one or more layers (e.g., layer(s) 545, layer(s) 645) of an insulation material may be deposited. The insulation material may be SiO₂, for example. In some embodiments, the one or more sheets of insulation material may be deposited by a HDP process.

In 990, one or more layers (e.g., layer(s) 548, layer(s) 648) of a passivation material may be deposited. The passivation material may be an insulation material (e.g., SiO₂).

FIG. 10 shows an example process 1000 for forming a structure having multiple TMR pillars per cushion pad, consistent with embodiments of the present disclosure. For example, process 1000 may be used to construct structure 700 of FIG. 7A.

As previously discussed, structures disclosed herein may be formed as a stack of materials. Construction of such a structure may begin with one or more sheets (e.g., sheet(s) 705) of an insulation material (e.g., SiO₂ or SiN). One or more additional sheets (e.g., sheet(s) 706) of insulation material (e.g., SiO₂ or SiN) may then be constructed and added to the stack, and in 1010 one or more layers (e.g., layer(s) 710) of metal substrate may be provided in these one or more additional sheets. For example, a metal substrate such as Al may be patterned into the one or more additional sheets. One or more additional sheets (e.g., sheet(s) 707) of an insulation material (e.g., SiO₂ or SiN) may then be constructed and added to the stack.

One or more additional sheets (e.g., sheet(s) 708) of an insulation material (e.g., SiO₂ or SiN) may then be constructed and added to the stack, and in 1020 one or more cushion pads (e.g., cushion pad(s) 720) may be provided in these sheets. For example, as previously discussed, these one or more cushion pads may be patterned into the one or more additional sheets and may be formed of a conductive material. In some embodiments, the cushion pad(s) may be formed to have a flat and smooth surface. The one or more cushion pads may be formed of TiN, Ti, CuN, or W, for example.

In 1030, one or more TMR elements may be formed. The one or more TMR elements may be TMR pillars (see, e.g., TMR pillar of FIG. 2, TMR pillar(s) 725), as previously discussed. The one or more TMR pillars may be constructed of multiple layers, such as TMR pillar 200 of FIG. 2. As previously discussed, TMR pillars may be constructed by first depositing the layers of the TMR pillars as sheets of materials in a TMR structure that extends across the structure (see, e.g., 825 of FIG. 8). One or more layers of materials may then be applied on top of the TMR structure and patterned onto the TMR structure (see, e.g., 835, 840 of FIG. 8). For example, one or more layers of a hard mask material may be applied on top of the TMR structure. The patterning of the layer(s) of hard mask may then be used to etch (e.g., using photolithography, ion beam etching, etc.) the TMR structure into separate TMR pillars (see, e.g., FIG. 8).

In 1040, one or more sheets (e.g., sheet(s) 735) of an insulation material may be deposited. The one or more sheets of insulation material may comprise an oxide layer processed with a low temperature (i.e., a low temperature oxide), such as SiO₂.

In 1050, one or more vias (e.g., via(s) 715, top via(s) 742) may be patterned into the one or more sheets of insulation material. For example, one or more top vias may be patterned into the one or more sheets of insulation material to provide access to the tops of the TMR elements. One or more additional vias may also be patterned and etched to provide access through the sheets of the insulation material and other sheets of the structure to the one or more layer(s) (e.g., layer(s) 710) of metal substrate. These one or more additional vias may then be filled with a conductive material, such as described previously for bottom via(s). Alternatively, these one or more additional vias may be filled with the conductive material of one or more layers (e.g., layer(s) 740) of jumper metal when the jumper metal is patterned.

In 1060, one or more layers (e.g., layer(s) 740) of a jumper metal may be patterned on top of the one or more sheets of insulation material and on top of the one or more TMR elements (through the top via(s)) to connect TMR elements together in any of various arrangements (e.g., connection arrangement 750). The layer(s) of jumper metal may comprise, for example, Al. In some embodiments, the one or more layers of jumper metal may also be patterned into the one or more additional vias that provide access to the one or more layers of metal substrate, thereby providing a conductive path to the one or more layers of the metal substrate.

In 1070, one or more layers (e.g., layer(s) 745) of an insulation material may be deposited. The insulation material may be SiO₂, for example. In some embodiments, the one or more sheets of insulation material may be deposited by a HDP process.

In 1080, one or more layers (e.g., layer(s) 748) of a passivation material may be deposited. The passivation material may be an insulation material (e.g., SiO₂).

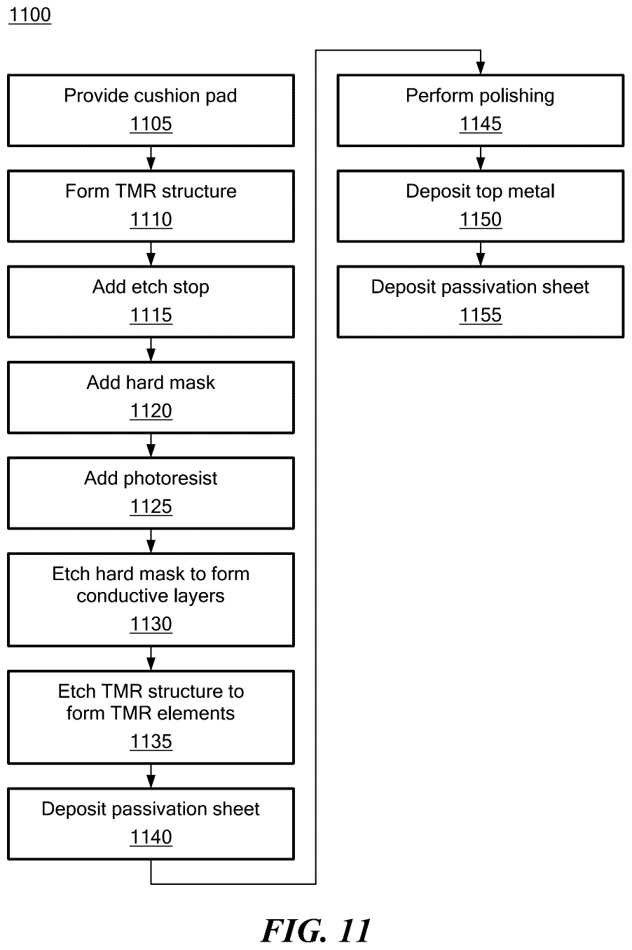

FIG. 11 shows an example process 1100 for forming a structure utilizing a conductive hard mask to connect a TMR pillar to a top metal, consistent with embodiments of the present disclosure. Process 1100 may be used to perform process 800 in FIG. 8 to construct a structure (e.g., structure 861).

As previously discussed, structures disclosed herein may be formed as a stack of materials. Construction of such a structure may begin with one or more sheets (e.g., sheet(s) 805) of an insulation material (e.g., SiO₂ or SiN). One or more additional sheets (e.g., sheet(s) 806) of an insulation material (e.g., SiO₂ or SiN) may then be constructed and added to the stack, and one or more layers (e.g., layer(s) 810) of metal substrate may be provided in these one or more additional sheets. For example, a metal substrate such as Al may be patterned into the one or more additional sheets.

One or more additional sheets (e.g., sheet(s) 807) of an insulation material (e.g., SiO₂ or SiN) may then be constructed and added to the stack and one or more bottom vias (e.g., bottom via(s) 815) may be provided in these sheets. For example, as previously discussed, these one or more bottom vias may be patterned into the sheets and may be filed with a conductive material, such as W.

One or more additional sheets (e.g., sheet(s) 808) of an insulation material (e.g., SiO₂ or SiN) may then be constructed and added to the stack, and in 1105 one or more cushion pads (e.g., cushion pad(s) 820) may be provided in these sheets. For example, as previously discussed, these one or more cushion pads may be patterned into the one or more additional sheets and may be formed of a conductive material. In some embodiments, the cushion pad(s) may be formed to have a flat and smooth surface. The one or more cushion pads may be formed of TiN, Ti, CuN, or W, for example.

In 1110, layers of a TMR pillar (see, e.g., FIG. 2) may be deposited as a TMR structure (e.g., TMR structure 825).

In 1115, one or more sheets (e.g., sheet(s) 830) of a conductive etch stop material may be deposited. The one or more sheets of conductive etch stop material may be deposited onto the TMR structure and may comprise a conductive material that does not get etched in a hard mask etching process. In some embodiments, the one or more sheets of conductive etch stop material may comprise TiN.

In 1120, one or more sheets (e.g., sheet(s) 835) of a conductive hard mask material may be deposited. The one or more sheets of conductive hard mask material may be deposited onto the one or more sheets of etch stop material and may comprise a conductive material that does get etched in a hard mask etching process. In some embodiments, the one or more sheets of conductive hard mask material may comprise Al, TiN, or CuN.

In 1125, one or more sheets of a photoresist material may be deposited and patterned into one or more photoresist pillars (e.g., photoresist pillar(s) 840) in the shape in which one or more TMR pillars are going to be patterned.

In 1130, the one or more layers of conductive hard mask material may be etched to form one or more pillars (e.g., pillar(s) 845) of conductive hard mask in the shape of the one or more photoresist pillars. The one or more pillars of photoresist material may then be lifted off the structure.

In 1135, ion beam etching may be performed on the structure to form one or more pillars of conductive etch stop material and one or more TMR pillars. After ion beam etching, the structure may comprise one or more conductive pillars, each of the one or more conductive pillars having a TMR pillar, a conductive pillar of etch stop material, and a pillar of conductive hard mask material.

In 1140, one or more sheets (e.g., sheet(s) 860) of a passivation material may be deposited onto the structure, covering the top surface of the structure (see, e.g., FIG. 8). The one or more sheets of passivation material may comprise an insulation material (e.g., SiO₂ or SiN).

In 1145, a chemical mechanical polishing and etchback process may be performed to polish and etch the one or more sheets of passivation material and the one or more pillars of conductive hard mask so that the surface at the top of the structure is flat and so that the tops of the one or more pillars of conductive hard mask are exposed.

In 1150, one or more layers (e.g., layer(s) 865) of a top metal (e.g., jumper metal) may be deposited and patterned on top of the structure, such that the one or more layers of top metal are connected to the top(s) of the one or more pillars of conductive hard mask. In doing so, the one or more TMR pillars are connected to the one or more layers of the top metal through the one or more pillars of conductive etch stop and through the one or more pillars of conductive hard mask. As previously discussed with respect to FIGS. 3A-7B, the one or more layers of top metal (e.g., jumper metal) may be deposited in various ways to connect the one or more TMR pillars in various arrangements, such as with series and/or parallel connections between TMR pillars.

In 1155, one or more sheets (e.g., sheet(s) 870) of a second passivation layer may be deposited, and one or more sheets (e.g., sheet(s) 875) of a third passivation layer may be deposited. The one or more sheets (e.g., sheet(s) 870) of the second passivation layer may comprise an LTO (e.g., SiO₂). The one or more sheets (e.g., sheet(s) 875) of the third passivation layer may comprise an insulation material (e.g., SiO₂ or SiN).

The processes and methods for constructing structures described herein may be performed as part of a manufacturing process for manufacturing a structure. One or more of the steps of these processes and methods may be performed by a machine. In some embodiments, one or more steps of these processes and methods may be performed by one type of machine (e.g., an ion beam etching machine) and one or more steps of these processes and methods may be performed by another type of machine (e.g., a high density plasma processing machine). In some embodiments, all steps of any of the processes or methods described herein may be performed by the same machine (e.g., a machine capable of ion beam etching and high density plasma processing). In some embodiments, one or more steps of the processes or methods described herein may be performed by one or more computers that automate a manufacturing process. For example, one or more computers may send instructions to manufacturing machines to perform the one or more steps of the methods and processes described herein. In some embodiments, one or more computers may perform all the steps for a method or process described herein. In some embodiments, a human may perform one or more steps of a method or process described herein, while a machine or computer may perform one or more other steps of the method or process.

The processes and methods described herein are not limited to the specific examples described. For example, the processes and methods are not limited to the specific order of steps described herein. Rather, any of the processing or method steps may be reordered, combined, removed, or performed in parallel or serially, as might be beneficial, to achieve the results described herein.

Although example structures (see, e.g., FIGS. 3A-8) are provided herein, the disclosure is not limited to the specific materials or configurations shown in these examples. One of skill in the art would recognize that materials may be removed, added, or moved, and connected in different arrangements, to achieve results consistent with embodiments of the present disclosure. One of ordinary skill in the art would also recognize that, although materials may be illustrated in FIGS. 3A-8 as having particular shapes, the disclosure is not so limited. For example, although TMR pillars, cushion pads, and vias may be illustrated in the figures as having particular shapes (e.g., circular, square, rectangular, cylindrical, conical, cuboid), the disclosure is not so limited. A person of ordinary skill in the art would recognize that materials disclosed herein may be constructed in a wide variety of different shapes, and those different shapes should be considered to be within the scope of the disclosure herein.

Various embodiments of the systems, methods, and techniques are described herein with reference to the related drawings. Alternative embodiments can be devised without departing from the scope of the described concepts. It is noted that various connections and positional relationships (e.g., over, below, adjacent, etc.) are set forth between elements in the foregoing description and in the drawings. These connections and/or positional relationships, unless specified otherwise, can be direct or indirect, and the present invention is not intended to be limiting in this respect. Accordingly, a coupling of entities can refer to either a direct or an indirect coupling, and a positional relationship between entities can be a direct or indirect positional relationship. As an example of an indirect positional relationship, references in the present description to element or structure A over element or structure B include situations in which one or more intermediate elements or structures (e.g., element C) is between elements A and B regardless of whether the characteristics and functionalities of elements A and/or B are substantially changed by the intermediate element(s).

Furthermore, it should be appreciated that relative, directional or reference terms (e.g. such as “above,” “below,” “left,” “right,” “top,” “bottom,” “vertical,” “horizontal,” “front,” “back,” “rearward,” “forward,” etc.) and derivatives thereof are used only to promote clarity in the description of the figures. Such terms are not intended as, and should not be construed as, limiting. Such terms may simply be used to facilitate discussion of the drawings and may be used, where applicable, to promote clarity of description when dealing with relative relationships, particularly with respect to the illustrated embodiments. Such terms are not, however, intended to imply absolute relationships, positions, and/or orientations. For example, with respect to an object or structure, an “upper” or “top” surface can become a “lower” or “bottom” surface simply by turning the object over. Nevertheless, it is still the same surface and the object remains the same. Also, as used herein, “and/or” means “and” or “or,” as well as “and” and “or.”

The terms “disposed over,” “overlying,” “atop,” “on top,” “positioned on” or “positioned atop” mean that a first element, such as a first structure, is present on a second element, such as a second structure, where intervening elements or structures (such as an interface structure) may or may not be present between the first element and the second element. The term “direct contact” means that a first element, such as a first structure, and a second element, such as a second structure, are connected without any intermediary elements or structures between the interface of the two elements. The term “connection” can include an indirect connection and a direct connection.

When discussing measurements or dimensions of materials herein, it should be understood that those measurements or dimensions may not be exact, and rather should be considered to include measurements or dimensions that are +/− 0-20% of the value given to account for, for example, manufacturing tolerances. For example, a value of 0.5 microns should be considered to encompass anywhere from 0.4-0.6 microns. Likewise, a description that one material has a surface with the same surface area as a surface of another material should be interpreted to mean that the surface areas are within +/− 0-20% of each other.

In the foregoing detailed description, various features are grouped together in one or more individual embodiments for the purpose of streamlining the disclosure. This method of disclosure is not to be interpreted as reflecting an intention that each claim requires more features than are expressly recited therein. Rather, inventive aspects may lie in less than all features of each disclosed embodiment.

References in the disclosure to “one embodiment,” “an embodiment,” “some embodiments,” or variants of such phrases indicate that the embodiment(s) described can include a particular feature, structure, or characteristic, but every embodiment can include the particular feature, structure, or characteristic. Moreover, such phrases are not necessarily referring to the same embodiment(s). Further, when a particular feature, structure, or characteristic is described with reference to one embodiment, knowledge of one skilled in the art may be relied upon to affect such feature, structure, or characteristic in connection with other embodiments whether or not explicitly described.

The disclosed subject matter is not limited in its application to the details of construction and to the arrangements of the components set forth in the following description or illustrated in the drawings. The disclosed subject matter is capable of other embodiments and of being practiced and carried out in various ways. As such, those skilled in the art will appreciate that the conception, upon which this disclosure is based, may readily be utilized as a basis for the designing of other structures, methods, and systems for carrying out the several purposes of the disclosed subject matter. Therefore, the claims should be regarded as including such equivalent constructions insofar as they do not depart from the spirit and scope of the disclosed subject matter.

Although the disclosed subject matter has been described and illustrated in the foregoing exemplary embodiments, it is understood that the present disclosure has been made only by way of example, and that numerous changes in the details of implementation of the disclosed subject matter may be made without departing from the spirit and scope of the disclosed subject matter.

All publications and references cited herein are expressly incorporated herein by reference in their entirety.

1. A structure, comprising:
a first conductive layer;
a second conductive layer;
a third conductive layer;
a first set of at least two tunneling magnetoresistance (TMR) elements in direct contact with the first conductive layer and with the second conductive layer, each of the at least two TMR elements of the first set comprising a free layer, a barrier layer, and a reference layer; and
a second set of at least two TMR elements in direct contact with the third conductive layer and with the second conductive layer, each of the at least two TMR elements of the second set comprising a free layer, a barrier layer, and a reference layer.

2. The structure of claim 1, wherein
each of the at least two TMR elements of the first set has a first surface in direct contact with the first conductive layer and a second surface in direct contact with the second conductive layer, and
each of the at least two TMR elements of the second set has a first surface in direct contact with the third conductive layer and a second surface in direct contact with the second conductive layer.

3. The structure of claim 1, wherein each of the first conductive layer and the third conductive layer comprises Titanium Nitride (TiN).

4. The structure of claim 1, wherein the second conductive layer comprises one of Copper (Cu) or Aluminum (Al).

5. The structure of claim 2, wherein the first surface of each of the at least two TMR elements of the first set is in direct contact with a first side of the first conductive layer, and an area of the first side of the first conductive layer is greater than a combined area of the first surfaces of the at least two TMR elements of the first set.

6. The structure of claim 1, wherein each of the at least two TMR elements of the first set is in direct contact with a first side of the first conductive layer, and a second side of the first conductive layer is in direct contact with a plurality of vias, each of the vias being filled with a conductive material for electrically connecting the first conductive layer to a metal substrate.

7. The structure of claim 1, wherein resistances of a TMR element of the first set and a TMR element of the second set are connected in series.

8. The structure of claim 1, wherein resistances of each of the at least two TMR elements in the first set are connected in parallel.

9. The structure of claim 1, wherein each of the at least two TMR elements in the first set is in direct contact with a first side of the first conductive layer, and a second side of the first conductive layer is in direct contact with a first via, the first via being filled with a conductive material for electrically connecting the first conductive layer to a first metal substrate, the structure further comprising:
a fourth conductive layer indirectly coupled to the first conductive layer, wherein the fourth conductive layer is in direct contact with a second via, the second via being filled with a conductive material for electrically connecting the fourth conductive layer to a second metal substrate.

10. The structure of claim 9, further comprising a third metal substrate configured for connection to a current source such that, when current is applied to the third metal substrate, the third metal substrate heats and radiates a magnetic field that changes a biasing in each of the at least two TMR elements in the first set and in each of the at least two TMR elements in the second set.

11. The structure of claim 9, further comprising:
a third set of at least two TMR elements in direct contact with the fourth conductive layer, each of the at least two TMR elements of the third set comprising a free layer, a barrier layer, and a reference layer.

12. The structure of claim 11, further comprising a fifth conductive layer, wherein a TMR element of the third set has a first surface in direct contact with the third conductive layer and a second surface in direct contact with the fifth conductive layer, the fifth conductive layer being indirectly coupled to the first conductive layer.

13. The structure of claim 1, wherein a first side of the second conductive layer is in direct contact with each of the at least two TMR elements of the first set and is further in direct contact with at least one via, the at least one via being filled with a conductive material for electrically connecting the second conductive layer to a metal substrate.

14. A method for forming a structure, comprising:
providing a first conductive layer and a second conductive layer on a substrate;
forming a tunnel magnetoresistance (TMR) structure on the first conductive layer and the second conductive layer, the TMR structure comprising at least a reference layer, a barrier layer, and a free layer;
depositing a mask metal layer on top of the TMR structure;
forming a third conductive layer and a fourth conductive layer from the mask metal layer;
forming a first TMR element and a second TMR element from the TMR structure; and
depositing a top metal layer onto the third conductive layer and the fourth conductive layer,
wherein the first TMR element is coupled to the top metal layer through the third conductive layer and the second TMR element is coupled to the top metal layer through the fourth conductive layer.

15. The method of claim 14, further comprising:
providing a first via in the substrate, the first via being filled with a conductive material; and
providing the first conductive layer in direct contact with the first via.

16. The method of claim 14, further comprising:
depositing an etch stop material in direct contact with the TMR structure; and
depositing the mask metal layer in direct contact with the etch stop material.

17. The method of claim 16, further comprising:
depositing a photoresist material in a pattern on top of the mask metal layer;
etching the mask metal layer based on the pattern of the photoresist material to form the third conductive layer and the fourth conductive layer; and
removing the photoresist material.

18. The method of claim 17, further comprising etching the TMR structure with an ion beam etching process to form the first TMR element and the second TMR element.

19. The method of claim 18, further comprising depositing a passivation layer over the first conductive layer, second conductive layer, third conductive layer, fourth conductive layer, first TMR element, and second TMR element.

20. The method of claim 19, further comprising performing a chemical mechanical polishing process to etch back the passivation layer, such that a top of the third conductive layer and a top of the fourth conductive layer are exposed.

21. The method of claim 20, further comprising depositing the top metal layer onto the top of the third conductive layer and the top of the fourth conductive layer.

22. The method of claim 21, further comprising depositing one or more additional passivation layers over the top metal layer.

23. A structure, comprising:
a first conductive layer;
a second conductive layer;
a third conductive layer in direct contact with the second conductive layer; and
at least two tunneling magnetoresistance (TMR) elements in direct contact with the first conductive layer and indirectly coupled to the third conductive layer, each of the at least two TMR elements comprising a free layer, a barrier layer, and a reference layer,
wherein a first surface of one of the at least two TMR elements is coupled to a first surface of the second conductive layer via an etch stop material, and a surface area of the first surface of the one of the at least two TMR elements is the same as the surface area of the first surface of the second conductive layer.

24. The structure of claim 23, wherein the first surface of the second conductive layer is no wider than 0.5 microns.

25. The structure of claim 23, wherein the first conductive layer comprises Titanium Nitride (TiN).

26. The structure of claim 23, wherein the second conductive layer comprises one of Aluminum (Al), Titanium Nitride (TiN), or Copper Nitride (CuN).

27. The structure of claim 23, wherein the third conductive layer comprises one of Copper (Cu) or Aluminum (Al).

28. The structure of claim 23, wherein the etch stop material comprises titanium nitride (TiN).
